(19) United States
(12) Patent Application Publication
(10) Pub. No.: US 2018/0259581 A1
(43) Pub. Date: Sep. 13, 2018

(54) DYNAMICALLY CONTROLLING VOLTAGE PROVIDED TO THREE-DIMENSIONAL (3D) INTEGRATED CIRCUITS (ICs) (3DICs) TO ACCOUNT FOR PROCESS VARIATIONS MEASURED ACROSS INTERCONNECTED IC TIERS OF 3DICs

(71) Applicant: QUALCOMM Incorporated, San Diego, CA (US)

(72) Inventors: Xia Li, San Diego, CA (US); Wei-Chuan Chen, San Diego, CA (US); Wah Nam Hsu, San Diego, CA (US); Yang Du, Carlsbad, CA (US)

(21) Appl. No.: 15/455,253

(22) Filed: Mar. 10, 2017

(51) Int. Cl. G01R 31/3185; H01L 21/66; H01L 27/06; H01L 23/528; H01L 23/34; H03K 3/03; H03K 17/14

(52) U.S. Cl. CPC G01R 31/318513; H01L 22/34; H01L 27/0688; H03K 17/14; H01L 23/34; H03K 3/0315; H01L 23/5286

(57) ABSTRACT

Dynamically controlling voltage provided to three-dimensional (3D) integrated circuits (ICs) (3DICs) to account for process variations measured across interconnected IC tiers of 3DICs are disclosed herein. In one aspect, a 3DIC process variation measurement circuit (PVMC) is provided to measure process variation. The 3DIC PVMC includes stacked logic PVMCs configured to measure process variations of devices across multiple IC tiers and process variations of vias that interconnect multiple IC tiers. The 3DIC PVMC may include IC tier logic PVMCs configured to measure process variations of devices on corresponding IC tiers. These measured process variations can be used to dynamically control supply voltage provided to the 3DIC such that operation of the 3DIC approaches a desired process corner. Adjusting supply voltage using the 3DIC PVMC takes into account interconnected properties of the 3DIC such that the supply voltage is adjusted to cause the 3DIC to operate in the desired process corner.

### BACKGROUND

### I. Field of the Disclosure

The technology of the disclosure relates generally to three-dimensional (3D) integrated circuits (ICs) (3DICs), and more particularly to controlling supply voltage provided to 3DICs.

### II. Background

Computing devices employ various integrated circuits (ICs) designed to achieve a multitude of functions related to operation of the computing devices. Increasingly complex ICs have been designed and manufactured to provide greater functionality. Concurrent with the increases in complexity of the ICs, there has been pressure to decrease the footprint consumed by the ICs. In a traditional two-dimensional (2D) IC (2DIC), electrical components such as processor cores, memory chips, and logic circuits are disposed in a single semiconductor IC tier. However, as complexity of ICs continues to increase, it becomes more difficult to achieve footprint reductions in a 2DIC.

A three-dimensional (3D) IC (3DIC) addresses design challenges of the 2DIC by stacking multiple semiconductor IC tiers in an integrated semiconductor die. In particular, a 3DIC employs devices, such as logic gates formed from transistors, disposed on multiple IC tiers that are interconnected using a plurality of through-silicon-vias (TSVs). Each IC tier is comprised of a wafer manufactured independently from the other IC tiers. As a result of being manufactured independently of one another, each IC tier in a 3DIC conventionally has different process variations compared to other IC tiers. Differing process variations across IC tiers may cause devices on each respective IC tier to operate at different speeds. More specifically, process variations can cause process corner variations that change the speed at which current flows through devices, such as the switching speed of transistors, thus affecting the frequency at which such devices operate on each IC tier. For example, such process variations can result in a 3DIC with a first IC tier characterized in a slow-slow (SS) corner, a second IC tier in a fast-fast (FF) corner, and a third IC tier in a typical-typical (TT) corner.

In this regard, a 3DIC is conventionally designed to operate in the TT corner so as to achieve a desired frequency while consuming a desired amount of power. One method used to operate a 3DIC closer to the TT corner involves including additional elements to address the SS and/or FF corners resulting from process variations. For example, power voltage temperature (PVT) sensors can be used to monitor the critical path of each IC tier so as to determine the supply voltage needed for the 3DIC to operate in the TT corner. However, changing the supply voltage of the 3DIC using the PVT sensors on each IC tier may not result in the 3DIC operating in the TT corner, thus reducing margin and yield for the 3DIC.

### SUMMARY OF THE DISCLOSURE

Aspects disclosed herein include dynamically controlling voltage provided to three-dimensional (3D) integrated circuits (ICs) (3DICs) to account for process variations measured across interconnected IC tiers of 3DICs. Related devices, methods, and systems are also disclosed. Process variations in the fabrication of 3DICs can lead to variations in the operating speed of devices such as transistors disposed on multiple IC tiers of a 3DIC, as well as the operating speed of vias used to interconnect multiple IC tiers. For example, process variations can result in a 3DIC with a first IC tier characterized in a slow-slow (SS) corner, a second IC tier in a fast-fast (FF) corner, and a third IC tier in a typical-typical (TT) corner. At a fixed supply voltage, such process variations can result in generation of a current that is either too low or too high to achieve the TT corner performance desired in the 3DIC. One method used to operate a 3DIC closer to the TT corner involves employing power voltage temperature (PVT) sensors to monitor the critical path of each IC tier independently so as to determine the supply voltage such that the 3DIC operates in the TT corner. However, because PVT sensors are used to determine the supply voltage of the 3DIC based on each IC tier independently of other IC tiers, PVT sensors do not account for the interconnected properties of a 3DIC. Adjusting the supply voltage without consideration of the interconnected properties of a 3DIC prevents such adjustments from addressing the overall properties of the 3DIC, which makes it difficult to adjust the supply voltage such that the 3DIC operates in the TT corner.

Thus, exemplary aspects disclosed herein include dynamically controlling voltage provided to 3DICs to account for process variations measured across interconnected IC tiers of 3DICs. In exemplary aspects, a 3DIC process variation measurement circuit (PVMC) is provided to measure process variation across interconnected IC tiers of a 3DIC. In particular, the 3DIC PVMC includes one or more stacked logic PVMCs configured to measure process variations of devices disposed across multiple interconnected IC tiers of the 3DIC that affect the delay and power consumption of the 3DIC, as well as the process corner in which the 3DIC operates. By measuring the process variations across interconnected IC tiers of the 3DIC, the 3DIC PVMC is also able to measure process variations of vias that interconnect the multiple interconnected IC tiers that also affect the delay and power consumption of the 3DIC, as well as the process corner of the 3DIC. The 3DIC PVMC may also optionally include IC tier logic PVMCs configured to measure process variations of devices disposed on corresponding IC tiers of the 3DIC. These measured process variations of the 3DIC can be used to dynamically control a supply voltage provided to the 3DIC such that the operation of the 3DIC approaches the desired process corner (e.g., TT corner). Further, the measurements of the 3DIC PVMC can be used to adjust supply voltage (i.e., adjust voltage domains) of each IC tier independently of one another. In other words, adjusting the supply voltage using the process variations of devices and vias across interconnected IC tiers measured by the 3DIC PVMC takes into account the interconnected properties of the 3DIC as well as the properties of each IC tier such that the supply voltage is adjusted to cause the 3DIC to operate in the desired process corner.

In this regard in one aspect, a 3DIC PVMC for measuring process variation across interconnected IC tiers of a 3DIC is provided. The 3DIC PVMC comprises a supply voltage input configured to receive a supply voltage coupled to the 3DIC. The 3DIC PVMC also comprises one or more stacked logic PVMCs coupled to the supply voltage input. Each stacked logic PVMC comprises a plurality of logic circuits each comprising one or more measurement transistors of a metal-oxide semiconductor (MOS) type. Each logic circuit of the plurality of logic circuits is disposed on a corresponding IC tier of a plurality of IC tiers of the 3DIC. Each stacked logic PVMC also comprises a stacked logic measurement output. Each stacked logic PVMC is configured to generate, on the corresponding stacked logic measurement output, a stacked process variation measurement voltage signal representing process variation of devices disposed on each corresponding IC tier of the plurality of IC tiers and process variation of a plurality of vias interconnecting the plurality of IC tiers as a function of coupling the supply voltage to the corresponding stacked logic PVMC.

In another aspect, a 3DIC PVMC for measuring process variation across interconnected IC tiers of a 3DIC is provided. The 3DIC PVMC comprises a means for receiving a supply voltage coupled to the 3DIC. The 3DIC PVMC also comprises one or more means for measuring stacked device process variation across a plurality of IC tiers of the 3DIC coupled to the means for receiving the supply voltage. Each of the one or more means for measuring stacked device process variation comprises a means for generating a stacked process variation measurement voltage signal representing process variation of devices disposed on each corresponding IC tier of the plurality of IC tiers and process variation of a plurality of vias interconnecting the plurality of IC tiers as a function of coupling the supply voltage to the corresponding means for measuring stacked device process variation.

In another aspect, a method of measuring process variation across interconnected IC tiers of a 3DIC is provided. The method comprises receiving a supply voltage coupled to the 3DIC. The method also comprises coupling the supply voltage from a supply voltage input to one or more stacked logic PVMCs. Each stacked logic PVMC comprises a plurality of logic circuits each comprising one or more measurement transistors of a MOS type, wherein each logic circuit of the plurality of logic circuits is disposed on a corresponding IC tier of a plurality of IC tiers of the 3DIC. Each stacked logic PVMC also comprises a stacked logic measurement output. The method also comprises generating a stacked process variation measurement voltage signal corresponding to each stacked logic PVMC representing process variation of devices disposed on each corresponding IC tier of the plurality of IC tiers and process variation of a plurality of vias interconnecting the plurality of IC tiers as a function of coupling the supply voltage to the corresponding stacked logic PVMC.

In another aspect, a 3DIC system is provided. The 3DIC system comprises a power management circuit configured to generate a supply voltage. The 3DIC system also comprises a 3DIC. The 3DIC comprises a plurality of IC tiers each comprising a plurality of devices of a MOS type. The 3DIC also comprises a plurality of vias interconnecting the plurality of IC tiers. The 3DIC also comprises a 3DIC PVMC for measuring process variation of devices in the 3DIC. The 3DIC PVMC comprises a supply voltage input configured to receive the supply voltage coupled to the 3DIC. The 3DIC PVMC also comprises one or more stacked logic PVMCs coupled to the supply voltage input. Each stacked logic PVMC comprises a plurality of logic circuits each comprising one or more measurement transistors of the MOS type, wherein each logic circuit of the plurality of logic circuits is disposed on a corresponding IC tier of the plurality of IC tiers of the 3DIC. Each stacked logic PVMC also comprises a stacked logic measurement output. Each stacked logic PVMC is configured to generate, on the corresponding stacked logic measurement output, a stacked process variation measurement voltage signal representing process variation of devices disposed on each corresponding IC tier of the plurality of IC tiers and process variation of the plurality of vias interconnecting the plurality of IC tiers as a function of coupling the supply voltage to the corresponding stacked logic PVMC. The power management circuit is further configured to receive the stacked process variation measurement voltage signal from each stacked logic PVMC. The power management circuit is further configured to determine one or more supply voltage levels based on the received stacked process variation measurement voltage signals. The power management circuit is further configured to dynamically generate one or more supply voltages at the determined one or more supply voltage levels.

### BRIEF DESCRIPTION OF THE FIGURES

FIG. 1 is a graph illustrating exemplary process corner variations in various integrated circuit (IC) tiers of a three-dimensional (3D) IC (3DIC) attributable to process variations related to fabrication of the devices in the 3DIC;

FIG. 2 is a schematic diagram illustrating an exemplary 3DIC system that includes an exemplary 3DIC employing an exemplary 3DIC process variation measurement circuit (PVMC) for measuring process variation across interconnected IC tiers of the 3DIC, which can be used by a power management circuit to dynamically control a supply voltage provided to the 3DIC to account for such process variations;

FIG. 3 is a flowchart illustrating an exemplary process that can be performed by the 3DIC system in FIG. 2 using the 3DIC PVMC for measuring process variations across interconnected IC tiers of the 3DIC and dynamically controlling the supply voltage provided to the 3DIC to account for such process variations;

FIG. 4 is a schematic diagram of another exemplary 3DIC system that includes an exemplary 3DIC employing an exemplary 3DIC PVMC designed using ring oscillator circuits to measure process variations across interconnected IC tiers of the 3DIC, which can be used by a power management circuit to dynamically control a supply voltage provided to the 3DIC to account for such process variations;

FIG. 5A is a schematic diagram of an exemplary stacked logic PVMC in the 3DIC PVMC in FIG. 4 employing a stacked ring oscillator circuit that employs AND-based logic circuits (e.g., NAND logic circuits) for measuring process variations of logic circuits dominated by N-type metal-oxide semiconductor (MOS) (NMOS) transistors;

FIG. 5B is a schematic diagram of an exemplary stacked logic PVMC in the 3DIC PVMC in FIG. 4 employing a stacked ring oscillator circuit that employs OR-based logic circuits (e.g., NOR logic circuits) for measuring process variations in logic circuits dominated by P-type MOS (PMOS) transistors;

FIG. 5C is a schematic diagram of an exemplary IC tier logic PVMC in the 3DIC PVMC in FIG. 4 employing a ring oscillator circuit that employs AND-based logic circuits (e.g., NAND logic circuits) for measuring process variations of logic circuits dominated by NMOS transistors;

FIG. 5D is a schematic diagram of an exemplary IC tier logic PVMC in the 3DIC PVMC in FIG. 4 employing a ring oscillator circuit that employs OR-based logic circuits (e.g., NOR logic circuits) for measuring process variations in logic circuits dominated by PMOS transistors;

FIG. 6A is an exemplary equation used to calculate a supply voltage to be distributed in a 3DIC based on process variations of multiple types of devices employed in each IC tier of the 3DIC and vias that interconnect the multiple IC tiers in the 3DIC, such as the 3DIC in FIG. 4, based on measurements generated by stacked logic ring oscillator circuits of the 3DIC;

FIG. 6B is an exemplary equation used to calculate a supply voltage to be distributed in a 3DIC based on process variations of multiple types of devices employed in each IC tier of the 3DIC, such as the 3DIC in FIG. 4, based on measurements generated by IC tier logic ring oscillator circuits on each IC tier of the 3DIC;

FIG. 7 is a schematic diagram of another exemplary 3DIC system that includes an exemplary three (3) IC tier 3DIC employing an exemplary 3DIC PVMC designed using ring oscillator circuits to measure process variation of devices across interconnected IC tiers of the 3DIC, which can be used by a power management circuit to dynamically control a supply voltage provided to each IC tier of the 3DIC either on a per-IC tier basis or to multiple IC tiers to account for such process variations;

FIG. 8 is a schematic diagram of another exemplary 3DIC PVMC designed using a stacked ring oscillator circuit, wherein the 3DIC PVMC employs two logic circuits in each stage of a stacked logic ring oscillator circuit in each IC tier;

FIG. 9 is a block diagram of an exemplary processor-based system that can be provided in a 3DIC system that includes a 3DIC PVMC for measuring process variations across interconnected IC tiers of the 3DIC, which can be used by a power management circuit to dynamically control a supply voltage provided to the 3DIC to account for such process variations, including but not limited to the 3DIC systems of FIGS. 2, 4, and 7; and

FIG. 10 is a block diagram of an exemplary wireless communications device that includes radio-frequency (RF) components, wherein the RF components can be provided in a 3DIC system that includes a 3DIC PVMC for measuring process variations across interconnected IC tiers of the 3DIC, which can be used by a power management circuit to dynamically control a supply voltage provided to the 3DIC to account for such process variations, including but not limited to the 3DIC systems of FIGS. 2, 4, and 7.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include dynamically controlling voltage provided to three-dimensional (3D) integrated circuits (ICs) (3DICs) to account for process variations measured across interconnected IC tiers of 3DICs. Related devices, methods, and systems are also disclosed. Process variations in the fabrication of 3DICs can lead to variations in the operating speed of devices such as transistors disposed on multiple IC tiers of a 3DIC, as well as the operating speed of vias used to interconnect multiple IC tiers. For example, process variations can result in a 3DIC with a first IC tier characterized in a slow-slow (SS) corner, a second IC tier in a fast-fast (FF) corner, and a third IC tier in a typical-typical (TT) corner. At a fixed supply voltage, such process variations can result in generation of a current that is either too low or too high to achieve the TT corner performance desired in the 3DIC. One method used to operate a 3DIC closer to the TT corner involves employing power voltage temperature (PVT) sensors to monitor the critical path of each IC tier independently so as to determine the supply voltage such that the 3DIC operates in the TT corner. However, because PVT sensors are used to determine the supply voltage of the 3DIC based on each IC tier independently of other IC tiers, PVT sensors do not account for the interconnected properties of a 3DIC. Adjusting the supply voltage without consideration of the interconnected properties of a 3DIC prevents such adjustments from addressing the overall properties of the 3DIC, which makes it difficult to adjust the supply voltage such that the 3DIC operates in the TT corner.

Thus, exemplary aspects disclosed in the detailed description include dynamically controlling voltage provided to 3DICs to account for process variations measured across interconnected IC tiers of 3DICs. In exemplary aspects, a 3DIC process variation measurement circuit (PVMC) is provided to measure process variation across interconnected IC tiers of a 3DIC. In particular, the 3DIC PVMC includes one or more stacked logic PVMCs configured to measure process variations of devices disposed across multiple interconnected IC tiers of the 3DIC that affect the delay and power consumption of the 3DIC, as well as the process corner in which the 3DIC operates. By measuring the process variations across interconnected IC tiers of the 3DIC, the 3DIC PVMC is also able to measure process variations of vias that interconnect the multiple interconnected IC tiers that also affect the delay and power consumption of the 3DIC, as well as the process corner of the 3DIC. The 3DIC PVMC may also optionally include IC tier logic PVMCs configured to measure process variations of devices disposed on corresponding IC tiers of the 3DIC. These measured process variations of the 3DIC can be used to dynamically control a supply voltage provided to the 3DIC such that the operation of the 3DIC approaches the desired process corner (e.g., TT corner). Further, the measurements of the 3DIC PVMC can be used to adjust supply voltage (i.e., adjust voltage domains) of each IC tier independently of one another. In other words, adjusting the supply voltage using the process variations of devices and vias across interconnected IC tiers measured by the 3DIC PVMC takes into account the interconnected properties of the 3DIC as well as the properties of each IC tier such that the supply voltage is adjusted to cause the 3DIC to operate in the desired process corner.

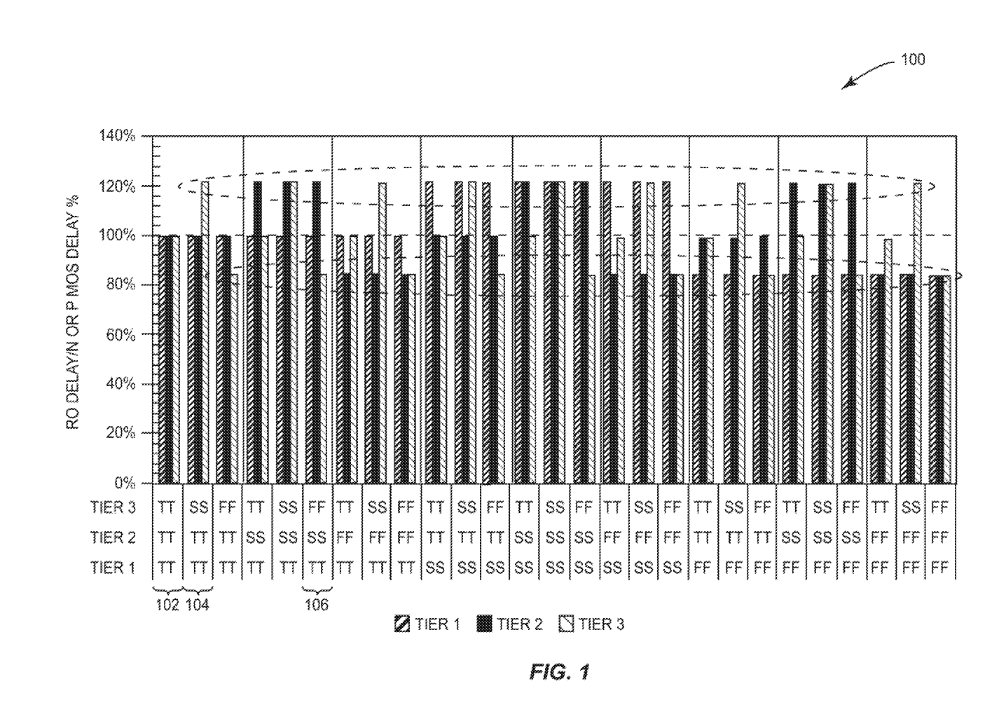

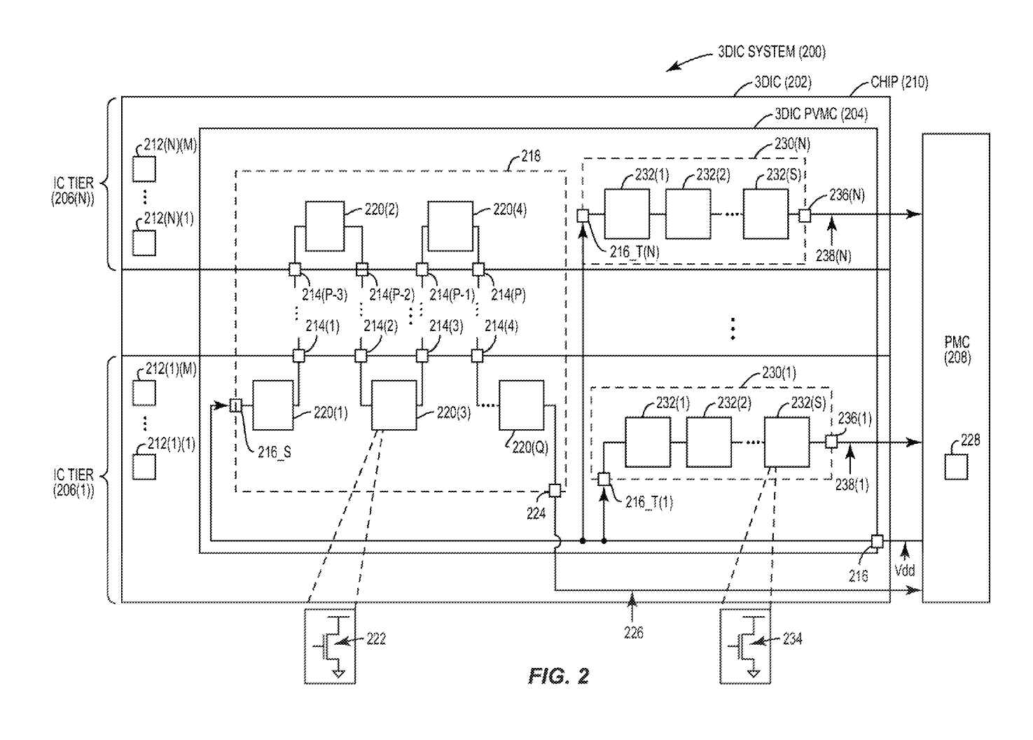

Before discussing exemplary 3DIC PVMCs for measuring process variations across interconnected IC tiers of a 3DIC, which can be used to dynamically control a supply voltage provided to the 3DIC to account for such process variations beginning in FIG. 2, a discussion of delay and power consumption of devices employed in various IC tiers of a 3DIC caused by process variations is first described with regard to FIG. 1.

In this regard, FIG. 1 is a graph 100 of exemplary process corner variations in various IC tiers of a 3DIC attributable to process variations related to fabrication of the devices in the 3DIC. More specifically, the graph 100 illustrates the process corner variations of a three (3) IC tier 3DIC, wherein the three IC tiers include Tier1, Tier2, and Tier3. The x-axis of the graph 100 represents the process corner variations in which each IC tier of the 3DIC may operate due to process variations of devices such as metal-oxide semiconductor (MOS) transistors. Additionally, the y-axis of the graph 100 represents a percentage of delay relative to a typical-typical (TT) corner for each IC tier. For example, an entry 102 of the x-axis corresponds to Tier1, Tier2, and Tier3 all operating in the TT corner such that the delays for Tier1, Tier2, and Tier3 correspond to 100% of the TT corner on the y-axis. In other words, the entry 102 indicates that Tier1, Tier2, and Tier3 achieve the TT corner at a corresponding fixed supply voltage using the chip/circuit design of the 3DIC with specific design margin coverage overhead.

On the other hand, with continuing reference to FIG. 1, an entry 104 of the x-axis corresponds to Tier1 and Tier2 operating in the TT corner, and Tier3 operating in a slow-slow (SS) corner. Thus, the delays of Tier1 and Tier2 correspond to 100% of the TT corner on the y-axis, while the delay of Tier3 corresponds to 120% of the TT corner (i.e., Tier3 operates 20% slower than the TT corner due to process variation). In this manner, the entry 104 indicates that Tier1 and Tier2 achieve the TT corner at a corresponding fixed supply voltage, while Tier3 may achieve the TT corner with a higher supply voltage level to speed up the devices of Tier3 from 120% of the TT corner to 100%. As another example, entry 106 of the x-axis corresponds to Tier1 operating in the TT corner, Tier2 operating in the SS corner, and Tier3 operating in a fast-fast (FF) corner. Thus, the delays of Tier1, Tier2, and Tier3 correspond to 100%, 120%, and 80%, respectively, of the TT corner. In this manner, the entry 106 indicates that Tier1 achieves the TT corner at the fixed supply voltage. However, Tier2 may achieve the TT corner if a higher supply voltage level is employed to speed up the devices of Tier2 from 120% of the TT corner to 100%. Further, Tier3 may achieve the TT corner with a lower supply voltage level to slow down the devices of Tier3 from 80% of the TT corner to 100%. However, adjusting the supply voltage such that Tier1, Tier2, and Tier3 achieve the TT corner may not cause the overall 3DIC to operate in the TT corner. Rather, the 3DIC may operate in the TT corner if any supply voltage adjustment also takes the interconnected properties of the 3DIC into account. For example, taking into account the delay associated with vias that interconnect Tier1, Tier2, and Tier3, as well as the delay associated with signals exchanged between devices across IC tier boundaries, may provide better control in adjusting the supply voltage to achieve the TT corner. Additionally, taking into account the power consumption of the 3DIC corresponding to Tier1, Tier2, and Tier3 in conjunction with the delay may provide further control in adjusting the supply voltage.

In this regard, FIG. 2 illustrates an exemplary 3DIC system 200 that includes an exemplary 3DIC 202 employing an exemplary 3DIC PVMC 204 for measuring process variation across interconnected IC tiers 206(1)-206(N) of the 3DIC 202. Such measurements can be used by a power management circuit (PMC) 208 to dynamically control a supply voltage Vdd provided to the 3DIC 202 employed in a chip 210 to account for such process variations. More specifically, each IC tier 206(1)-206(N) employs corresponding devices (212(1)(1)-212(1)(M))-(212(N)(1)-212(N)(M)) (also referred to as 212(1)(1)-212(N)(M)) of a metal oxide semiconductor (MOS) type, wherein the IC tiers 206(1)-206(N) are interconnected by vias 214(1)-214(P). As a non-limiting example, the devices 212(1)(1)-212(N)(M) may be N-type or P-type MOS (e.g., NMOS or PMOS) transistors configured to form multiple logic gates that perform various logic functions. Additionally, each IC tier 206(1)-206(N) may be a section of semiconductor material, such as a silicon chip or wafer, having at least one active device, such as a transistor, wherein the section of semiconductor material is disposed over a substrate. Further, each via 214(1)-214(P) may be a vertical electrical connection that passes through each IC tier 206(1)-206(N), such as a through-silicon via (TSV), so as to interconnect the corresponding IC tiers 206(1)-206(N).

With continuing reference to FIG. 2, the 3DIC PVMC 204 is provided to measure process variation across the IC tiers 206(1)-206(N) of the 3DIC 202. In particular, the 3DIC PVMC 204 includes a supply voltage input 216 configured to receive the supply voltage Vdd coupled to the 3DIC 202. In this regard, the 3DIC PVMC 204 is configured to receive the supply voltage Vdd generated by the power management circuit 208 in this example. A stacked logic PVMC 218 is included in the 3DIC PVMC 204 and configured to measure process variations of the devices 212(1)(1)-212(N)(M) and vias 214(1)-214(P) that affect the delay and power consumption of the 3DIC 302, as well as the process corner in which the 3DIC 202 operates. In particular, the stacked logic PVMC 218 includes a stacked supply voltage input 216_S coupled to the supply voltage input 216. Further, the stacked logic PVMC 218 includes logic circuits 220(1)-220(Q), each of which is disposed on an IC tier 206(1)-206(N) and includes one or more measurement transistors 222 of a MOS type (i.e., measurement MOS transistors 222). The stacked logic PVMC 218 is configured to generate, on a stacked logic measurement output 224, a stacked process variation measurement voltage signal 226 representing process variation of the devices 212(1)(1)-212(N)(M) disposed on each corresponding IC tier 206(1)-206(N) and the process variation of the vias 214(1)-214(P) as a function of coupling the supply voltage Vdd to the stacked logic PVMC 218.

In particular, because each of the logic circuits 220(1)-220(Q) are fabricated using the same die/wafer process as the devices 212(1)(1)-212(N)(M) on each corresponding IC tier 206(1)-206(N) in this example, each measurement transistor 222 will have the same or similar global process variations as in the corresponding devices 212(1)(1)-212(N)(M). Thus, the performance of the logic circuits 220(1)-220(Q) can be measured to represent the die/wafer process variations in the devices 212(1)(1)-212(N)(M) in the 3DIC 202, because the logic circuits 220(1)-220(Q) should experience the same or similar delay and power consumption as the corresponding devices 212(1)(1)-212(N)(M). Further, because the stacked logic PVMC 218 also measures the process variations of the vias 214(1)-214(P), the stacked logic PVMC 218 takes into account the interconnected properties of the 3DIC 202. In this manner, by measuring the process variations of the devices 212(1)(1)-212(N)(M) and the vias 214(1)-214(P), the measurement of the stacked logic PVMC 218 should represent the same or similar delay and power consumption as the 3DIC 202. Additionally, as discussed in more detail below, although the 3DIC PVMC 204 in this aspect includes one (1) stacked logic PVMC 218, other aspects may include multiple stacked logic PVMCs 218.

With continuing reference to FIG. 2, the power management circuit 208 is configured to receive the stacked process variation measurement voltage signal 226 from the stacked logic PVMC 218. The power management circuit 208 is also configured to determine a supply voltage level based on the received stacked process variation measurement voltage signal 226. The power management circuit 208 is configured to then dynamically generate the supply voltage Vdd based on the supply voltage level to provide power to consuming components of the 3DIC 202 for operation in a desired process corner (e.g., the TT corner), including the devices 212(1)(1)-212(N)(M). As will be discussed in more detail below, the power management circuit 208 may include a memory 228 configured to store parameters/characterizations indicative of the process variation of the devices 212(1)(1)-212(N)(M) that can then be used to determine the supply voltage level used to generate the supply voltage Vdd. The memory 228 can be a one-time programmable (OTP) memory as an example. Further, the power management circuit 208 in this example may be provided as a power management integrated circuit (PMIC) employed in hardware, software, or a combination of both hardware and software.

With continuing reference to FIG. 2, generating the supply voltage Vdd using the stacked process variation measurement voltage signal 226 allows the power management circuit 208 to adjust the supply voltage Vdd provided to the 3DIC 202 based on the process variation of the devices 212(1)(1)-212(N)(M), as well as the vias 214(1)-214(P). In this manner, the 3DIC PVMC 204 takes into account the interconnected properties of the 3DIC 202 such that the supply voltage Vdd can be dynamically adjusted to cause the 3DIC 202 to operate in the TT corner with more granularity and accuracy compared to adjusting the supply voltage Vdd while only considering the process variations of the devices 212(1)(1)-212(N)(M) on each corresponding IC tier 206(1)-206(N). For example, if the effect of the determined process variations in the 3DIC 202 based on the received stacked process variation measurement voltage signal 226 is that the 3DIC 202 operates in the SS corner at the current fixed supply voltage Vdd, the power management circuit 208 can dynamically increase the supply voltage Vdd to account for the devices 212(1)(1)-212(N)(M) functioning too slowly, thus increasing performance of the 3DIC 202 to the TT corner. However, if the effect of the determined process variations in the devices 212(1)(1)-212(N)(M) based on the received stacked process variation measurement voltage signal 226 is that the 3DIC 202 operates in the FF corner at the current fixed supply voltage Vdd, the power management circuit 208 can dynamically decrease the supply voltage Vdd to account for the devices 212(1)(1)-212(N)(M) functioning too quickly, thus decreasing power of the 3DIC 202.

With continuing reference to FIG. 2, the 3DIC PVMC 204 may also optionally include IC tier logic PVMCs 230(1)-230(N) disposed on corresponding IC tiers 206(1)-206(N) and configured to measure process variations of the devices 212(1)(1)-212(N)(M) of the corresponding IC tiers 206(1)-206(N). In particular, each IC tier logic PVMC 230(1)-230(N) includes an IC tier supply voltage input 216_T(1)-216_T(N) coupled to the supply voltage input 216. Each IC tier logic PVMC 230(1)-230(N) also includes logic circuits 232(1)-232(S) that include one or more measurement transistors 234 of a MOS type (i.e., measurement MOS transistors 234). Additionally, each IC tier logic PVMC 230(1)-230(N) is configured to generate, on a corresponding logic measurement output 236(1)-236(N), a logic process variation measurement voltage signal 238(1)-238(N) representing process variation of the devices 212(1)(1)-212(N)(M) disposed on the corresponding IC tier 206(1)-206(N) as a function of coupling the supply voltage Vdd to the IC tier logic PVMCs 230(1)-230(N). In particular, because the logic circuits 232(1)-232(S) are fabricated using the same die/wafer process as the devices 212(1)(1)-212(N)(M) of the corresponding IC tier 206(1)-206(N) in this example, each measurement transistor 234 will have the same or similar global process variations as the corresponding devices 212(1)(1)-212(N)(M). Thus, the performance of the logic circuits 232(1)-232(S) can be measured to represent the process variations in the devices 212(1)(1)-212(N)(M) of the corresponding IC tier 206(1)-206(N) in the 3DIC 202, because the logic circuits 232(1)-232(S) should experience the same or similar delay and power consumption as the devices 212(1)(1)-212(N)(M). In this manner, the measurement of the logic circuits 232(1)-232(S) should represent the same or similar delay and power consumption as the corresponding IC tiers 206(1)-206(N). As discussed in more detail below, although the 3DIC PVMC 204 in this aspect includes one (1) IC tier logic PVMC 230(1)-230(N) per IC tier 206(1)-206(N), other aspects may include multiple IC tier logic PVMCs 230(1)-230(N) per IC tier 206(1)-206(N).

With continuing reference to FIG. 2, the power management circuit 208 can also be configured to receive the logic process variation measurement voltage signals 238(1)-238(N), determine the supply voltage levels based on the received stacked process variation measurement voltage signal 226 and the logic process variation measurement voltage signals 238(1)-238(N), and dynamically generate the supply voltage Vdd at the determined supply voltage level similar to the process described above. Generating the supply voltage Vdd using the stacked process variation measurement voltage signal 226 and the logic process variation measurement voltage signals 238(1)-238(N) allows the power management circuit 208 to adjust the supply voltage Vdd provided to the 3DIC 202 based on the process variation of the devices 212(1)(1)-212(N)(M) and the vias 214(1)-214(P), as well as the devices 212(1)(1)-212(N)(M) of each corresponding IC tier 206(1)-206(N) independently. Providing such information to the 3DIC PVMC 204 allows the supply voltage Vdd to be adjusted with further accuracy and granularity.

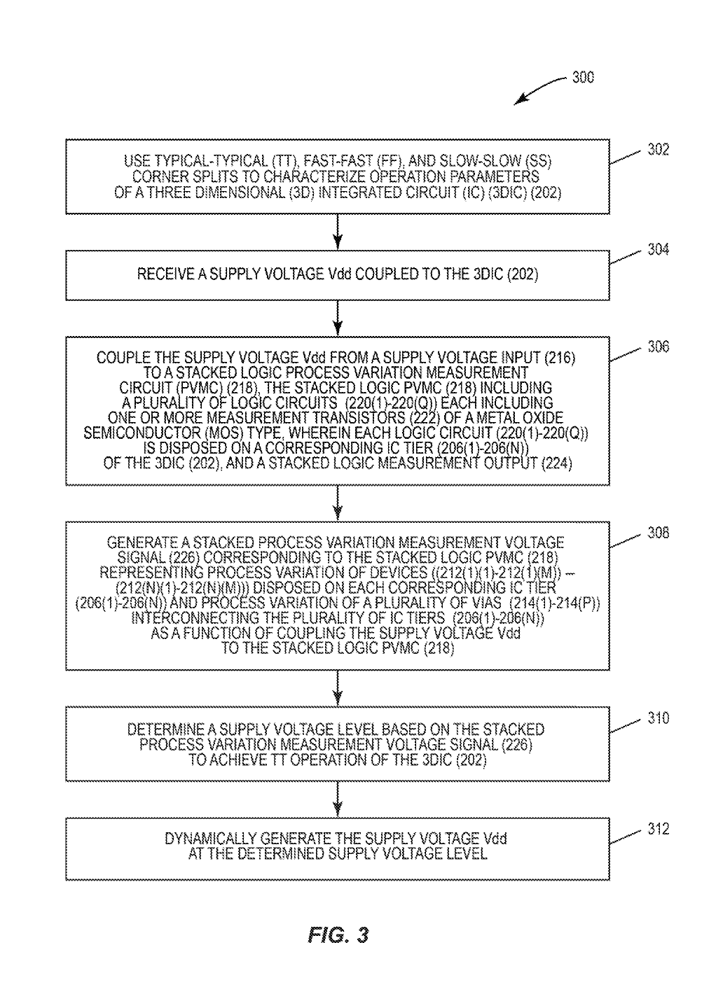

FIG. 3 illustrates an exemplary process 300 that can be performed by the 3DIC system 200 in FIG. 2 using the 3DIC PVMC 204 for measuring process variations across the interconnected IC tiers 206(1)-206(N) of the 3DIC 202 and dynamically controlling the supply voltage Vdd provided to the 3DIC 202 to account for such process variations. In particular, the process 300 includes the power management circuit 208 using TT, FF, and SS corner splits determined during the design phase of the 3DIC 202 to characterize operation parameters of the 3DIC 202 (block 302). The process 300 also includes the 3DIC PVMC 204 receiving the supply voltage Vdd coupled to the 3DIC 202 (block 304). Additionally, the process 300 includes coupling the supply voltage Vdd from the supply voltage input 216 to the stacked logic PVMC 218 that includes the logic circuits 220(1)-220(Q) disposed on the corresponding IC tier 206(1)-206(N) of the 3DIC 202 and the stacked logic measurement output 224 (block 306). As described above, each of the logic circuits 220(1)-220(Q) is fabricated using the same die/wafer process as the devices 212(1)(1)-212(N)(M) on each corresponding IC tier 206(1)-206(N) in this example. The process 300 further includes generating the stacked process variation measurement voltage signal 226 corresponding to the stacked logic PVMC 218 representing process variations of the devices 212(1)(1)-212(N)(M) and the vias 214(1)-214(P) as a function of coupling the supply voltage Vdd to the stacked logic PVMC 218 (block 308). Further, the power management circuit 208 determines the supply voltage level based on the stacked process variation measurement voltage signal 226, as well as the characterizations generated using the TT, SS, and FF corner splits, to achieve TT corner operation of the 3DIC 202 (block 310). The power management circuit 208 uses the stacked process variation measurement voltage signal 226 and the logic process variation measurement voltage signals 238(1)-238(N) to dynamically generate the supply voltage Vdd at the determined supply voltage level wherein the supply voltage Vdd is provided to the 3DIC 202 (block 312).

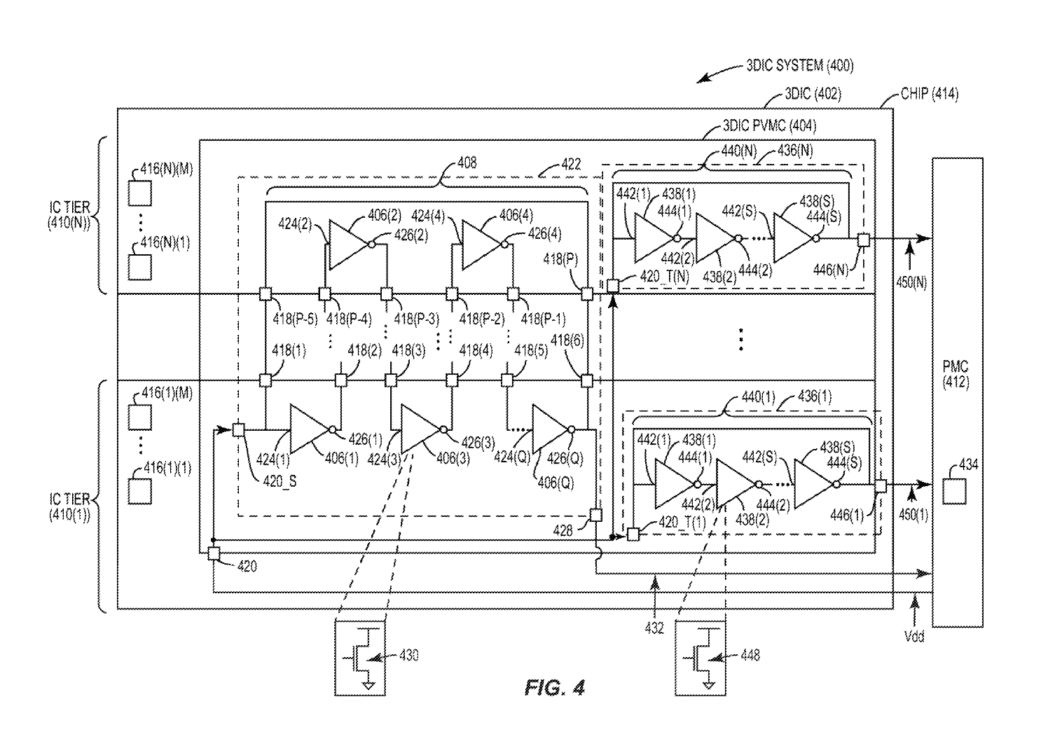

FIG. 4 illustrates an exemplary 3DIC system 400 that includes an exemplary 3DIC 402 employing an exemplary 3DIC PVMC 404 that uses logic circuits 406(1)-406(Q) employed as a stacked ring oscillator circuit 408 for measuring process variation across interconnected IC tiers 410(1)-410(N) of the 3DIC 402. Such measurements can be used by a power management circuit (PMC) 412 to dynamically control a supply voltage Vdd provided to the 3DIC 402 employed in a chip 414 to account for such process variations. More specifically, each IC tier 410(1)-410(N) employs corresponding devices (416(1)(1)-416(1)(M))-(416(N)(1)-416(N)(M)) (also referred to as 416(1)(1)-416(N)(M)) of a MOS type, wherein the IC tiers 410(1)-410(N) are interconnected by vias 418(1)-418(P).

With continuing reference to FIG. 4, the 3DIC PVMC 404 is provided to measure process variation of the devices 416(1)(1)-416(N)(M) across the IC tiers 410(1)-410(N). In particular, the 3DIC PVMC 404 includes a supply voltage input 420 configured to receive the supply voltage Vdd coupled to the 3DIC 402. The 3DIC PVMC 404 is configured to receive the supply voltage Vdd generated by the power management circuit 412 in this example. A stacked logic PVMC 422 is included in the 3DIC PVMC 404 that includes a supply voltage input 420_S coupled to the supply voltage input 420. Further, the stacked logic PVMC 422 is configured to measure process variations of the devices 416(1)(1)-416(N)(M) and vias 418(1)-418(P) using the stacked ring oscillator circuit 408 formed from the logic circuits 406(1)-406(Q), wherein Q is an odd number of at least three (3). Each logic circuit 406(1)-406(Q) includes a corresponding input node 424(1)-424(Q) and output node 426(1)-426(Q) such that the logic circuits 406(1)-406(Q) are interconnected to form the stacked ring oscillator circuit 408. In particular, the logic circuits 406(1)-406(Q) are interconnected such that each input node 424(1)-424(Q) is coupled to the output node 426(1)-426(Q) of the previous logic circuit 406(1)-406(Q), wherein the input node 424(1) of the first logic circuit 406(1) is coupled to the output node 426(Q) of the final logic circuit 406(Q), which is coupled to a stacked logic measurement output 428. Further, each logic circuit 406(1)-406(Q) includes one or more measurement transistors 430 of a MOS type (i.e., measurement MOS transistors 430). Similar to the logic circuits 220(1)-220(Q) in FIG. 2, each of the logic circuits 406(1)-406(Q) is fabricated using the same die/wafer process as the devices 416(1)(1)-416(N)(M) on each corresponding IC tier 410(1)-410(N) in this example.

With continuing reference to FIG. 4, the stacked logic PVMC 422 is configured to generate, on the stacked logic measurement output 428, a stacked process variation measurement voltage signal 432 representing process variation of the devices 416(1)(1)-416(N)(M) disposed on each corresponding IC tier 410(1)-410(N) and the process variation of the vias 418(1)-418(P) as a function of coupling the supply voltage Vdd to the stacked logic PVMC 422. In particular, because the logic circuits 406(1)-406(Q) are fabricated using the same process as the corresponding devices 416(1)(1)-416(N)(M) in this example, each measurement transistor 430 will have the same or similar global process variations as in the corresponding devices 416(1)(1)-416(N)(M). Thus, the performance of the logic circuits 406(1)-406(Q) can be measured to represent the process variations in the devices 416(1)(1)-416(N)(M) in each corresponding IC tier 410(1)-410(N) in the 3DIC 402, because the logic circuits 406(1)-406(Q) should experience the same or similar delay and power consumption as the corresponding devices 416(1)(1)-416(N)(M). In this manner, the measurement of the logic circuits 406(1)-406(Q) in conjunction with the vias 418(1)-418(P) should represent the same or similar delay and power consumption as the 3DIC 402.

With continuing reference to FIG. 4, the power management circuit 412 is configured to receive the stacked process variation measurement voltage signal 432 from the stacked logic PVMC 422. In this example, because the logic circuits 406(1)-406(Q) are formed as the stacked ring oscillator circuit 408, the stacked process variation measurement voltage signal 432 can be represented as a delay ti of the stacked ring oscillator circuit 408. More specifically, the delay ti of the stacked ring oscillator circuit 408 is proportional to the parasitic capacitance C of the logic circuits 406(1)-406(Q), the supply voltage V_{dd} provided to the logic circuits 406(1)-406(Q), and the effective current I_{eff} of the logic circuits 406(1)-406(Q), plus the delay T_{3d} of the vias 418(1)-418(P), as shown below in Equation 1:

$$τ ∝ \frac{CVdd}{Ieff} + {τ}_{3 d} \qquad Eq . 1$$

The power management circuit 412 is configured to determine a supply voltage level based on the received stacked process variation measurement voltage signal 432, a parameter ‘a’ indicative of the process variation of the devices 416(1)(1)-416(N)(M), and a parameter ‘b’ indicative of the process variation of the vias 418(1)-418(P), which is used to dynamically generate the supply voltage Vdd, as shown below in Equation 2:

$$Vdd = ( a * \frac{CVdd}{Ieff} ) + ( b * {τ}_{3 d} ) \qquad Eq . 2$$

In this regard, the supply voltage Vdd generated by the power management circuit 412 is used to provide power to consuming components of the 3DIC 402 for operation in the TT corner, including the devices 416(1)(1)-416(N)(M). The parameters ‘a’ and ‘b’ are generated by the power management circuit 412 using TT, FF, and SS corner splits determined during the design phase of the 3DIC 402 to characterize operation parameters of the 3DIC 402. For example, the parameters ‘a’ and ‘b’ may be indicative of the process variation of the devices 416(1)(1)-416(N)(M) and the vias 418(1)-418(P), respectively. The power management circuit 412 may include a memory 434 configured to store the parameters ‘a’ and ‘b’, as well as other parameters. Additionally, although not illustrated in Equations 1 and 2, other aspects may also take into account the power consumption of the logic circuits 406(1)-406(Q) when generating the stacked process variation measurement voltage signal 432 and calculating the supply voltage Vdd.

With continuing reference to FIG. 4, by generating the supply voltage Vdd using the stacked process variation measurement voltage signal 432, the power management circuit 412 can dynamically adjust the supply voltage Vdd provided to the 3DIC 402 based on the process variation of the devices 416(1)(1)-416(N)(M), as well as the vias 418(1)-418(P). In this manner, the 3DIC PVMC 404 takes into account the interconnected properties of the 3DIC 402 such that the supply voltage Vdd can be dynamically adjusted to cause the 3DIC 402 to operate in the TT corner with more granularity and accuracy compared to adjusting the supply voltage Vdd while only considering the process variations of the devices 416(1)(1)-416(N)(M).

With continuing reference to FIG. 4, the 3DIC PVMC 404 may also optionally include IC tier logic PVMCs 436(1)-436(N), each of which includes a corresponding supply voltage input 420_T(1)-420_T(N) configured to receive the supply voltage Vdd. Each IC tier logic PVMC 436(1)-436(N) also employs logic circuits 438(1)-438(S) disposed on the corresponding IC tiers 410(1)-410(N). In particular, each IC tier logic PVMC 436(1)-436(N) is configured to measure process variations of the corresponding devices 416(1)(1)-416(N)(M) on the corresponding IC tier 410(1)-410(N) using a corresponding ring oscillator circuit 440(1)-440(N) formed from the logic circuits 438(1)-438(S), wherein S is an odd number of at least three (3). Each logic circuit 438(1)-438(S) includes a corresponding input node 442(1)-442(S) and output node 444(1)-444(S) such that the logic circuits 438(1)-438(S) are interconnected to form the corresponding ring oscillator circuits 440(1)-440(N). In particular, the logic circuits 438(1)-438(S) are interconnected such that each input node 442(1)-442(S) is coupled to the output node 444(1)-444(S) of a previous logic circuit 438(1)-438(S), wherein the input node 442(1) of the first logic circuit 438(1) is coupled to the output node 444(S) of the final logic circuit 438(S), which is coupled to a corresponding logic measurement output 446(1)-446(N). Further, each logic circuit 438(1)-438(S) includes one or more measurement transistors 448 of a MOS type (i.e., measurement MOS transistors 448).

With continuing reference to FIG. 4, each IC tier logic PVMC 436(1)-436(N) is configured to generate, on each corresponding logic measurement output 446(1)-446(N), a respective logic process variation measurement voltage signal 450(1)-450(N) representing process variation of the devices 416(1)(1)-416(N)(M) disposed on the corresponding IC tier 410(1)-410(N) as a function of coupling the supply voltage Vdd to the IC tier logic PVMCs 436(1)-436(N). In particular, because the logic circuits 438(1)-438(S) are fabricated using the same die/wafer process as the devices 416(1)(1)-416(N)(M) on each corresponding IC tier 410(1)-410(N) in this example, each measurement transistor 448, and thus the logic circuits 438(1)-438(S) will have the same or similar global process variations as in the devices 416(1)(1)-416(N)(M) in the corresponding IC tier 410(1)-410(N). Thus, the performance of the logic circuits 438(1)-438(S) can be measured to represent the process variations in the devices 416(1)(1)-416(N)(M) of the corresponding IC tier 410(1)-410(N), because the logic circuits 438(1)-438(S) should experience the same or similar delay and power consumption as the corresponding devices 416(1)(1)-416(N)(M). In this manner, each of the measurements of the logic circuits 438(1)-438(S) should represent the same or similar delay and power consumption as the corresponding IC tier 410(1)-410(N).

With continuing reference to FIG. 4, the power management circuit 412 is also configured to receive the logic process variation measurement voltage signals 450(1)-450(N) from the IC tier logic PVMCs 436(1)-436(N). In this example, because the logic circuits 438(1)-438(S) are formed as the ring oscillator circuits 440(1)-440(N), the logic process variation measurement voltage signals 450(1)-450(N) can be represented as a delay τ of each corresponding ring oscillator circuit 440(1)-440(N). More specifically, the delay τ(i) of each ring oscillator circuit 440(i) is proportional to the parasitic capacitance C of the logic circuits 438(1)-438(S), the supply voltage V_{dd} provided to the logic circuits 438(1)-438(S), and the effective current I_{eff} of the logic circuits 438(1)-438(S), as shown below in Equation 3:

$$τ ( i ) ∝ \frac{CVdd}{Ieff} \qquad Eq . 3$$

The power management circuit 412 is configured to determine a supply voltage level and dynamically generate the supply voltage Vdd based on Equation 2 above, as well as the corresponding logic process variation measurement voltage signal 450(1)-450(N) (e.g., delay τ(i)) and the parameter ‘a’ indicative of the process variation of the devices 416(1)(1)-416(N)(M) on the corresponding IC tier 410(1)-410(N), as shown below in Equation 4:

$$Vdd ( tier i ) = ( a * \frac{CVdd}{Ieff} ) \qquad Eq . 4$$

In this regard, as discussed above, in addition to using information that takes into account the interconnected properties of the 3DIC 402 by way of Equation 2, the power management circuit 412 can also employ additional IC tier specific information using Equation 4 above for adjusting the supply voltage Vdd with more granularity. Alternatively, Equation 4 provides the power management circuit 412 the option to adjust the supply voltage Vdd using only the IC tier specific information. Additionally, although not illustrated in Equations 3 and 4, other aspects may also take into account the power consumption of the logic circuits 438(1)-438(S) when generating the logic process variation measurement voltage signals 450(1)-450(N) and calculating the supply voltage Vdd. Further, as described in more detail below, using Equation 2 and Equation 4 above, the power management circuit 412 can be configured to adjust the supply voltage Vdd provided to any combination of the IC tiers 410(1)-410(N), or adjust the supply voltage Vdd provided to an individual IC tier 410(1)-410(N). Thus, the power management circuit 412 has the flexibility to generate the supply voltage Vdd with a wide range of granularity based on the specific needs of the 3DIC 402.

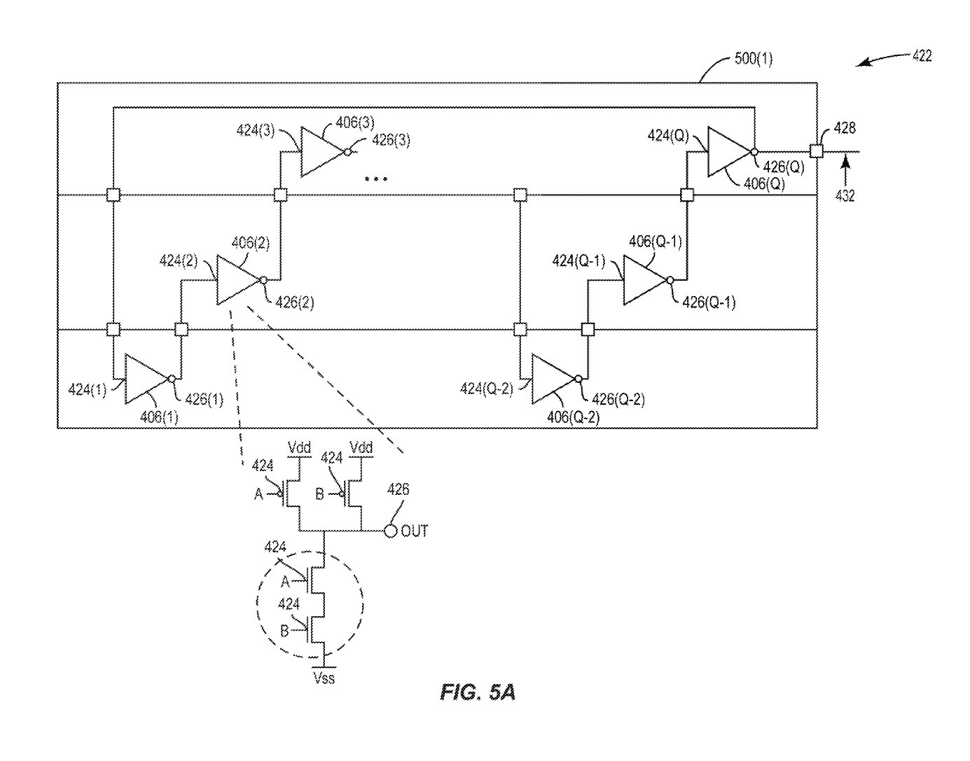

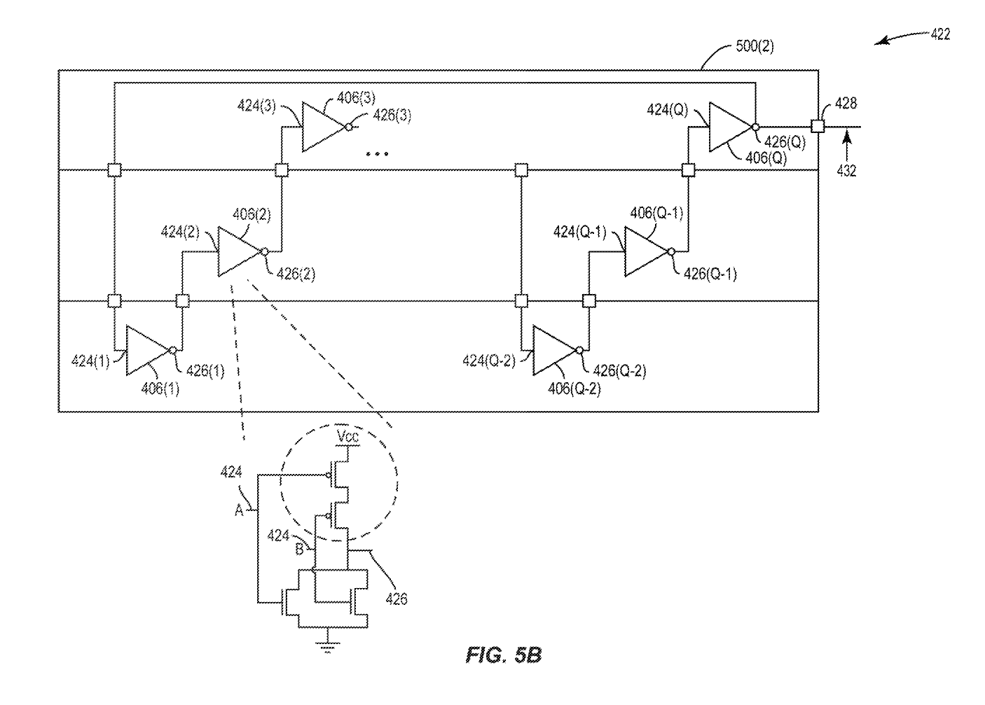

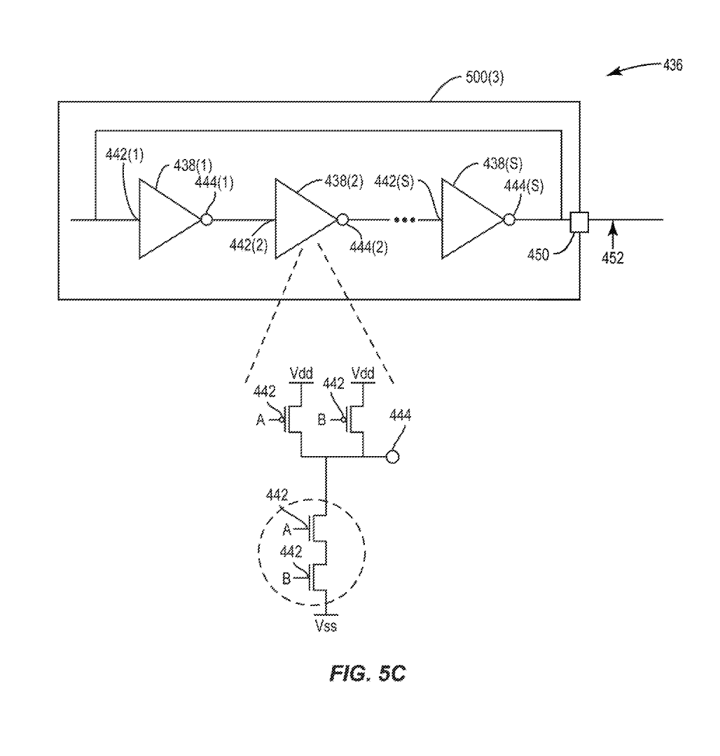

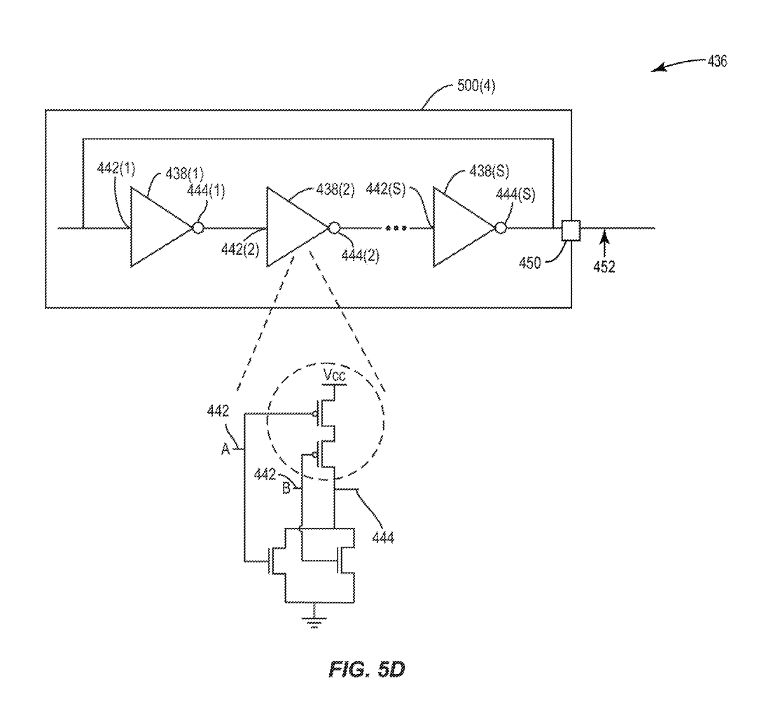

In addition to dynamically controlling the supply voltage Vdd based on the process variations of the devices 416(1)(1)-416(N)(M) generally, the 3DIC PVMC 404 can also be configured to adjust the supply voltage Vdd based on the type of the devices 416(1)(1)-416(N)(M). In this regard, FIGS. 5A and 5B provide exemplary instances of the stacked logic PVMC 422 that can be employed in the 3DIC PVMC 404 in FIG. 4. For example, as shown in FIG. 5A, if the process variation of the devices 416(1)(1)-416(N)(M) in the 3DIC 402 is dominated by N-type MOS (NMOS) transistors (e.g., the logic in the devices 416(1)(1)-416(N)(M) is designed using NMOS transistors), then the stacked logic PVMC 422 can be provided as a ring oscillator circuit 500(1) that includes the logic circuits 406(1)-406(Q) provided as AND-based logic circuits 406(1)-406(Q) (e.g., NAND logic circuits 406(1)-406(Q)). The ring oscillator circuit 500(1) (i.e., the AND-based ring oscillator circuit 500(1)) is configured to generate the stacked process variation measurement voltage signal 432 based on the performance of the NAND logic circuits 406(1)-406(Q) as affected by their process variations on the stacked logic measurement output 428. In this manner, the stacked process variation measurement voltage signal 432 can be represented as an N-type delay TN of the ring oscillator circuit 500(1). Additionally, although not included below, other aspects may also take into account the power consumption of the NAND logic circuits 406(1)-406(Q). The delay τN is proportional to the parasitic capacitance C of the NAND logic circuits 406(1)-406(Q), the supply voltage V_{dd} provided to the NAND logic circuits 406(1)-406(Q), and the effective current I_{N} of the NAND logic circuits 406(1)-406(Q), plus the delay τ_{3d} of the vias 418(1)-418(P), as shown below in Equation 5:

$$τ N ∝ \frac{CVdd}{IN} + {τ}_{3 d} \qquad Eq . 5$$

With reference to FIG. 5B, if the process variation of the devices 416(1)(1)-416(N)(M) in the 3DIC 402 is dominated by P-type MOS (PMOS) transistors (e.g., the logic in the devices 416(1)(1)-416(N)(M) is designed using PMOS transistors), then the stacked logic PVMC 422 can be provided as a ring oscillator circuit 500(2) that includes the logic circuits 406(1)-406(Q) provided as OR-based logic circuits 406(1)-406(Q) (e.g., NOR logic circuits 406(1)-406(Q)). The ring oscillator circuit 500(2) (i.e., the OR-based ring oscillator circuit 500(2)) is configured to generate the stacked process variation measurement voltage signal 432 based on the performance of the NOR logic circuits 406(1)-406(Q) as affected by their process variations on the stacked logic measurement output 428. In this manner, the stacked process variation measurement voltage signal 432 can be represented as a P-type delay τP of the ring oscillator circuit 500(2). Additionally, although not illustrated below, other aspects may also take into account the power consumption of the NOR logic circuits 406(1)-406(Q). The delay τP is proportional to the parasitic capacitance C of the NOR logic circuits 406(1)-406(Q), the supply voltage V_{dd} provided to the NOR logic circuits 406(1)-406(Q), and the effective current Iₚ of the NOR logic circuits 406(1)-406(Q), plus the delay τ_{3d} of the vias 418(1)-418(P), as shown below in Equation 6:

$$τ P ∝ \frac{CVdd}{IP} + {τ}_{3 d} \qquad Eq . 6$$

Further, FIGS. 5C and 5D provide exemplary IC tier logic PVMCs 436 that can be employed in the 3DIC PVMC 404 of FIG. 4. For example, as shown in FIG. 5C, if the process variation of the devices 416(1)(1)-416(N)(M) in the 3DIC 402 is dominated by NMOS transistors (e.g., the logic in the devices 416(1)(1)-416(N)(M) is designed using NMOS transistors), then the IC tier logic PVMCs 436(1)-436(N) can be provided as a ring oscillator circuit 500(3) that includes the logic circuits 438(1)-438(S) provided as AND-based logic circuits 438(1)-438(S) (e.g., NAND logic circuits 438(1)-438(S)) for each corresponding IC tier 410(1)-410(N). The ring oscillator circuit 500(3) (i.e., the AND-based ring oscillator circuit 500(3)) is configured to generate the logic process variation measurement voltage signals 450(1)-450(N) based on the performance of the NAND logic circuits 438(1)-438(S) as affected by their process variations on the corresponding logic measurement output 446(1)-446(N) for each corresponding IC tier 410(1)-410(N). In this manner, the logic process variation measurement voltage signals 450(1)-450(N) can be represented as an N-type delay τN of the ring oscillator circuit 500(3) for each corresponding IC tier 410(1)-410(N). Additionally, although not illustrated below, other aspects may also take into account the power consumption of the NAND logic circuits 438(1)-438(S). The delay τN is proportional to the parasitic capacitance C of the NAND logic circuits 438(1)-438(S), the supply voltage V_{dd} provided to the NAND logic circuits 438(1)-438(S), and the effective current I_{N} of the NAND logic circuits 438(1)-438(S), as shown below in Equation 7:

$$τ N ∝ \frac{CVdd}{IN} \qquad Eq . 7$$

With reference to FIG. 5D, if the process variation of the devices 416(1)(1)-416(N)(M) in the 3DIC 402 is dominated by PMOS transistors (e.g., the logic in the devices 416(1)(1)-416(N)(M) is designed using PMOS transistors), then the IC tier logic PVMCs 436(1)-436(N) can be provided as a ring oscillator circuit 500(4) (i.e., the OR-based ring oscillator circuit 500(4)) that includes logic circuits 438(1)-438(S) provided as OR-based logic circuits 438(1)-438(S) (e.g., NOR logic circuits 438(1)-438(S)) for each corresponding IC tier 410(1)-410(N). The ring oscillator circuit 500(4) is configured to generate the logic process variation measurement voltage signals 450(1)-450(N) based on the performance of the NOR logic circuits 438(1)-438(S) as affected by their process variations on the corresponding logic measurement output 446(1)-446(N) for each corresponding IC tier 410(1)-410(N). In this manner, the logic process variation measurement voltage signals 450(1)-450(N) can be represented as a P-type delay τP of the ring oscillator circuit 500(4) for each corresponding IC tier 410(1)-410(N). Additionally, although not illustrated below, other aspects may also take into account the power consumption of the NOR logic circuits 438(1)-438(S). The delay τP is proportional to the parasitic capacitance C of the NOR logic circuits 438(1)-438(S), the supply voltage V_{dd} provided to the NOR logic circuits 438(1)-438(S), and the effective current Iₚ of the NOR logic circuits 438(1)-438(S), as shown below in Equation 8:

$$τ P ∝ \frac{CVdd}{IP} \qquad Eq . 8$$

In addition to being configured to take into account the type of devices 416(1)(1)-416(N)(M) employed, the stacked logic PVMC 422 and the IC tier logic PVMCs 436(1)-436(N) can be configured to take into account the threshold voltage of the transistors employed in the devices 416(1)(1)-416(N)(M). For example, the stacked logic PVMC 422 and the IC tier logic PVMCs 436(1)-436(N) can perform measurements according to the performance of the devices 416(1)(1)-416(N)(M) operating in a specific power/voltage domain for each IC tier 410(1)-410(N). In this manner, it is possible to apply more than one power/voltage domain in each IC tier 410(1)-410(N) according to performance requirements and dynamic voltage adjustment in the IC tiers 410(1)-410(N), wherein a methodology can be used to generate dynamic supply voltage for each power/voltage domain. More specifically, the stacked ring oscillator circuit 408 and the ring oscillator circuits 440(1)-440(N) can be configured to generate the stacked process variation measurement voltage signal 432 and the logic process variation measurement voltage signals 450(1)-450(N), respectively, based on whether the devices 416(1)(1)-416(N)(M) employ high threshold voltage (HVT), standard threshold voltage (SVT), or low threshold voltage (LVT) transistors.

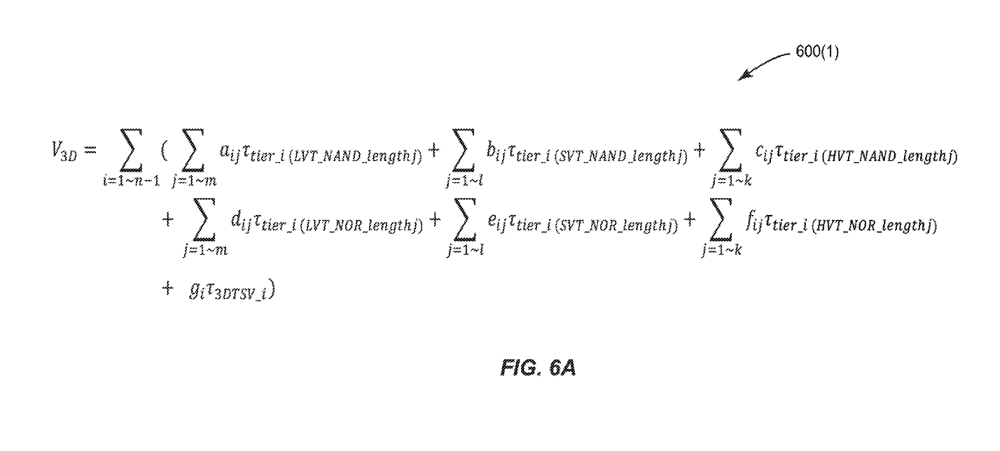

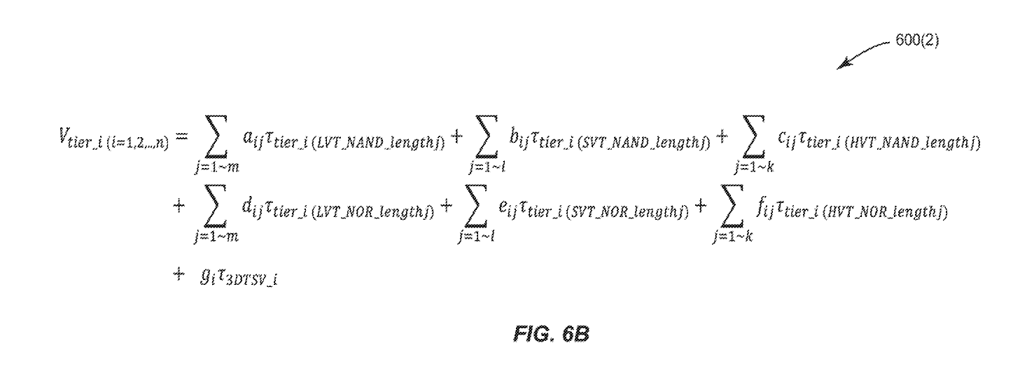

In this regard, FIG. 6A illustrates an exemplary equation 600(1) used by the power management circuit 412 in FIG. 4 to calculate a supply voltage Vdd (e.g., V_{3D}) to be distributed in the 3DIC 402 based on process variations of different types of devices 416(1)(1)-416(N)(M) employed in the corresponding IC tiers 410(1)-410(N), as well as process variations of the vias 418(1)-418(P) based on measurements generated by multiple type-specific stacked logic PVMCs 422(1)-422(T) employed in one (1) 3DIC PVMC, such as the 3DIC PVMC 404. The equation 600(1) is also reproduced herein below:

$${V}_{3 D} = {\sum }_{i = 1 ∼ n - 1} ( {\sum }_{j = 1 ∼ m} {a}_{ij} {τ}_{{tier}_{—} i ( {LVT}_{—} {NAND}_{—} lengthj )} + {\sum }_{j = 1 ∼ l} {b}_{ij} {τ}_{{tier}_{—} i ( {SVT}_{—} {NAND}_{—} lengthj )} + {\sum }_{j = 1 ∼ k} {c}_{ij} {τ}_{{tier}_{—} i ( {HVT}_{—} {NAND}_{—} lengthj )} + {\sum }_{j = 1 ∼ m} {d}_{ij} {τ}_{{tier}_{—} i ( {LVT}_{—} {NOR}_{—} lengthj )} + {\sum }_{j = 1 ∼ l} {e}_{ij} {τ}_{{tier}_{—} i ( {SVT}_{—} {NOR}_{—} lengthj )} + {\sum }_{j = 1 ∼ k} {f}_{ij} {τ}_{{tier}_{—} i ( {HVT}_{—} {NOR}_{—} lengthj )} + {ℊ}_{i} {τ}_{3 {DTSV}_{—} i} ) \qquad Eq . 600 ( 1 )$$

With reference to the equation 600(1), the supply voltage V_{3D} is equal or almost equal to a summation of process variation measurements determined by the following type-specific stacked logic PVMCs 422: LVT, NAND-based stacked logic PVMC 422; SVT, NAND-based stacked logic PVMC 422; HVT, NAND-based stacked logic PVMC 422; LVT, NOR-based stacked logic PVMC 422; SVT, NOR-based stacked logic PVMC 422; and HVT, NOR-based stacked logic PVMC 422. Further, the delay τ_{3DTSV}_{_}ᵢ attributable to the vias 418(1)-418(P) is also included in the summation of process variation measurements. The summation is calculated an ‘i’ number of times, wherein ‘i’ equals the range between 1 and n−1, wherein ‘n’ is the number of IC tiers. In this manner, the summation in the equation 600(1) includes a number of iterations equal to the number of interfaces between IC tiers 410(1)-410(N) (e.g., n−1). For example, if the 3DIC 402 includes three (3) IC tiers 410(1)-410(3), n is equal to three (3) such that the summation iterates for i=1 and i=2. Additionally, the equation 600(1) includes parameters ‘a’, ‘b’, ‘c’, ‘d’, ‘e’, and ‘f’ indicative of the process variation coefficients of the devices 416(1)(1)-416(N)(M), as well as the parameter ‘g’ indicative of the process variation coefficients of the vias 418(1)-418(P), similar to the parameters ‘a’ and ‘b’ discussed above with reference to Equations 2 and 4. Thus, the equation 600(1) can be used by the power management circuit 412 to calculate the supply voltage Vdd (e.g., V_{3D}) to provide to the entire 3DIC 402 based on the process variations of specific types of devices 416(1)(1)-416(N)(M), while also taking into account the interconnected properties of the 3DIC attributable to the vias 418(1)-418(P). In this manner, the equation 600(1) takes into account the average variation effect of the IC tiers 410(1)-410(N) to generate a dynamic supply voltage Vdd (e.g., V_{3D}) to overcome an overall 3D stack chip process variation effect. Additionally, although not illustrated in Equation 600(1), other aspects may include a value corresponding to the power consumption when calculating the supply voltage Vdd (e.g., V_{3D}).

Further, FIG. 6B illustrates an exemplary equation 600(2) used by the power management circuit 412 in FIG. 4 to calculate the supply voltage Vdd (e.g., Vₜᵢₑᵣ_{_}ᵢ) to be distributed in the 3DIC 402 based on process variations of different types of devices 416(1)(1)-416(N)(M) employed in the corresponding IC tier 410(1)-410(N) based on measurements generated by multiple type-specific IC tier logic PVMCs 436(1)-436(N). The equation 600(2) is also reproduced herein below:

$${V}_{{tier}_{—} i ( i = 1 , 2 , … , n )} = {\sum }_{j = 1 ∼ m} {a}_{ij} {τ}_{{tier}_{—} i ( {LVT}_{—} {NAND}_{—} lengthj )} + {\sum }_{j = 1 ∼ l} {b}_{ij} {τ}_{{tier}_{—} i ( {SVT}_{—} {NAND}_{—} lengthj )} + {\sum }_{j = 1 ∼ k} {c}_{ij} {τ}_{{tier}_{—} i ( {HVT}_{—} {NAND}_{—} lengthj )} + {\sum }_{j = 1 ∼ m} {d}_{ij} {τ}_{{tier}_{—} i ( {LVT}_{—} {NOR}_{—} lengthj )} + {\sum }_{j = 1 ∼ l} {e}_{ij} {τ}_{{tier}_{—} i ( {SVT}_{—} {NOR}_{—} lengthj )} + {\sum }_{j = 1 ∼ k} {f}_{ij} {τ}_{{tier}_{—} i ( {HVT}_{—} {NOR}_{—} lengthj )} + {ℊ}_{i} {τ}_{3 {DTSV}_{—} i} \qquad Eq . 600 ( 2 )$$

With reference to the equation 600(2), the supply voltage Vₜᵢₑᵣ_{_}ᵢ is equal or almost equal to a summation of process variation measurements determined by the following type-specific IC tier logic PVMCs 436(1)-436(N) employed on each IC tier 410(1)-410(N): LVT, NAND-based IC tier logic PVMC 436; SVT, NAND-based IC tier logic PVMC 436; HVT, NAND-based IC tier logic PVMC 436; LVT, NOR-based IC tier logic PVMC 436; SVT, NOR-based IC tier logic PVMC 436; and HVT, NOR-based IC tier logic PVMC 436. The delay τ_{3DTSV}_{_}ᵢ attributable to the vias 418(1)-418(P) is also included in the process variation measurements. In this manner, the equation 600(2) can be used to calculate the supply voltage Vₜᵢₑᵣ_{_}ᵢ for each individual IC tier 410(1)-410(N) (e.g., for each IC tier ‘i’), wherein multiple IC tier logic PVMCs 436(1)-436(N) are employed on each IC tier 410(1)-410(N) in individual power/voltage domains. For example, if the 3DIC 402 included three (3) IC tiers 410(1)-410(3), the supply voltage Vₜᵢₑᵣ_{_}ᵢ can be calculated for i=1, i=2, and i=3. Additionally, the equation 600(2) includes parameters ‘a’, ‘b’, ‘c’, ‘d’, ‘e’, and ‘f’ indicative of the process variation coefficients of the devices 416(1)(1)-416(N)(M) similar to the parameters discussed above with reference to Equations 2 and 4. Thus, the power management circuit 412 can control the supply voltage Vdd for each IC tier 410(1)-410(N) individually by determining the supply voltage Vdd using only the equation 600(2). The power management circuit 412 can also control the different supply voltage Vdd of each voltage domain for each IC tier 410(1)-410(N) individually by determining the supply voltage Vdd using only the corresponding type-specific portions of the equation 600(2). Alternatively, the power management circuit 412 can use the process variation measurement of each IC tier 410(1)-410(N) corresponding to the equation 600(2) in conjunction with the equation 600(1) to determine the supply voltage Vdd of the 3DIC 402. Additionally, although not illustrated in Equation 600(2), other aspects may include a value corresponding to the power consumption when calculating the supply voltage Vdd (e.g., Vₜᵢₑᵣ_{_}ᵢ).

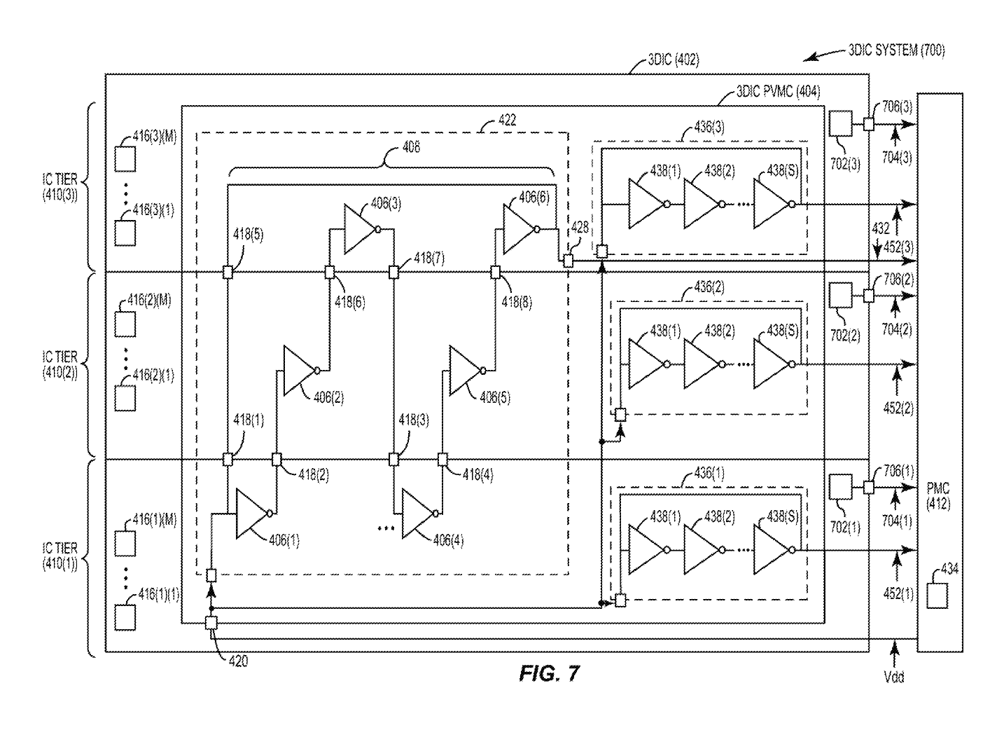

As a non-limiting example, FIG. 7 illustrates another exemplary 3DIC system 700. The 3DIC system 700 includes the 3DIC 402 with three (3) IC tiers 410(1)-410(3) and the 3DIC PVMC 404, which employs the stacked logic PVMC 422 and the IC tier logic PVMCs 436(1)-436(3). Other common components between the 3DIC system 700 in FIG. 7 and the 3DIC system 400 in FIG. 4 are shown with common element numbers in FIGS. 4 and 7, and thus will not be redescribed herein.

With continuing reference to FIG. 7, the vias 418(1)-418(4) interconnect the IC tiers 410(1), 410(2), and the vias 418(5)-418(8) interconnect the IC tiers 410(2), 410(3). Further, the logic circuits 406(1)-406(6) of the stacked ring oscillator circuit 408 of the stacked logic PVMC 422 are disposed on alternating IC tiers 410(1)-410(3). In this manner, the stacked logic PVMC 422 is configured to generate the stacked process variation measurement voltage signal 432 representing process variation of the devices (416(1)(1)-416(1)(M))-(416(3)(1)-416(3)(M)) (also referred to as 416(1)(1)-416(3)(M)) disposed on the corresponding IC tiers 410(1)-410(3) and the process variation of the vias 418(1)-418(8) as a function of coupling the supply voltage Vdd provided to the stacked logic PVMC 422. Additionally, each of the IC tier logic PVMCs 436(1)-436(3) employs the corresponding logic circuits 438(1)-438(3) disposed on the corresponding IC tiers 410(1)-410(3). The ring oscillator circuit 440(1)-440(3) of each corresponding IC tier logic PVMC 436(1)-436(3) is configured to generate the corresponding logic process variation measurement voltage signal 450(1)-450(3) representing process variation of the devices 416(1)(1)-416(3)(M) disposed on the corresponding IC tiers 410(1)-410(3) as a function of coupling the supply voltage Vdd to the IC tier logic PVMCs 436(1)-436(3). Further, the 3DIC system 700 also employs temperature sensors 702(1)-702(3) disposed on the corresponding IC tiers 410(1)-410(3), wherein each temperature sensor 702(1)-702(3) is configured to generate a temperature signal 704(1)-704(3) of the corresponding IC tier 410(1)-410(3) on a corresponding temperature output 706(1)-706(3). The temperature signals 704(1)-704(3) can be used by the power management circuit 412 in conjunction with the stacked process variation measurement voltage signal 432 and the logic process variation measurement voltage signals 450(1)-450(3) to dynamically control the supply voltage Vdd.

With continuing reference to FIG. 7, the power management circuit 412 may determine the supply voltage level to which to adjust the supply voltage Vdd using Equations 2 and 4 described above, or alternatively, the equations 600(1) and 600(2) in FIGS. 6A and 6B, respectively, in conjunction with the temperature signals 704(1)-704(3). For example, the power management circuit 412 may use either Equation 2 or the equation 600(1) to determine the supply voltage level to which to adjust the supply voltage Vdd provided to all three (3) IC tiers 410(1)-410(3). Alternatively, the power management circuit 412 may use Equation 2 or the equation 600(1) to determine the supply voltage level to which to adjust the supply voltage Vdd provided to the IC tiers 410(1), 410(2), and use Equation 4 or the equation 600(2) to determine the supply voltage Vdd provided to the IC tier 410(3). Further, the power management circuit 412 may use Equation 4 or the equation 600(2) to determine separate supply voltage levels to which to adjust the supply voltage Vdd for each IC tier 410(1)-410(3) independently of one another. In other words, the 3DIC PVMC 404 can provide an array of process variation measurements such that the power management circuit 412 has the flexibility to generate the supply voltage Vdd with a wide range of granularity based on the specific needs of the 3DIC 402.

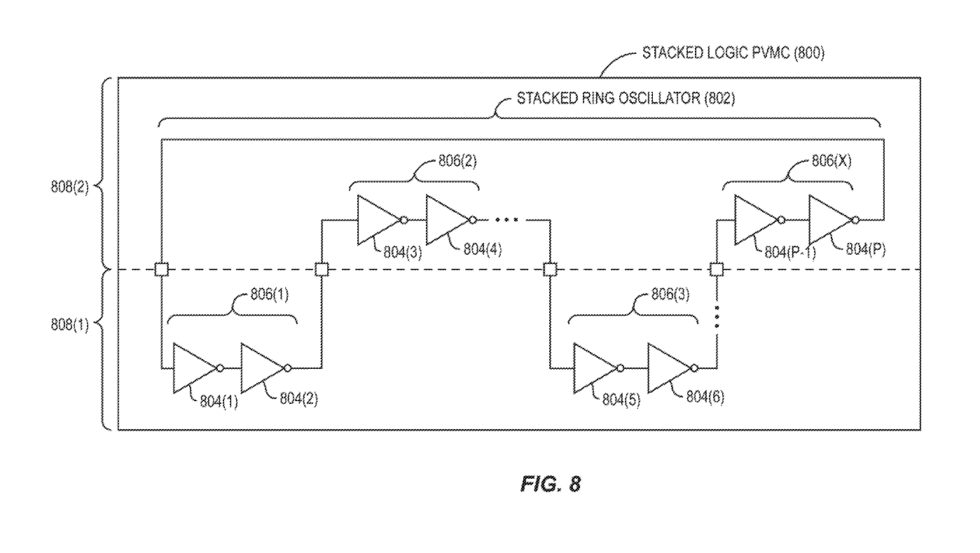

Additionally, although the stacked logic PVMC 422 employs the logic circuits 406(1)-406(6) of the stacked ring oscillator circuit 408 on alternating IC tiers 410(1)-410(3) in FIG. 7, other aspects may employ the logic circuits 406(1)-406(6) in a different formation. In this regard, FIG. 8 illustrates another exemplary stacked logic PVMC 800 designed using a stacked ring oscillator circuit 802. More specifically, the stacked ring oscillator circuit 802 employs two logic circuits 804(1)-804(P) in each stage 806(1)-806(X) of the stacked ring oscillator circuit 802 in each IC tier 808(1), 808(2). For example, the stage 806(1) includes the logic circuits 804(1), 804(2) on the IC tier 808(1), while the stage 806(2) includes the logic circuits 804(3), 804(4) on the IC tier 808(2). In this manner, the logic circuits of the stacked ring oscillator circuits in aspects described herein can be disposed in a variety of formations across the multiple IC tiers of the 3DIC while providing the process variation measurements needed to dynamically control the supply voltage Vdd.

The elements described herein are sometimes referred to as means for performing particular functions. In this regard, the supply voltage input 216 is sometimes referred to herein as “a means for receiving a supply voltage coupled to the 3DIC.” The stacked logic PVMC 218 is sometimes referred to herein as “one or more means for measuring stacked device process variation across a plurality of IC tiers of the 3DIC coupled to the means for receiving the supply voltage.” The IC tier logic PVMCs 230(1)-230(N) are sometimes referred to herein as “one or more means for measuring IC tier device process variation corresponding to an IC tier of the plurality of IC tiers of the 3DIC coupled to the means for receiving the supply voltage.” Additionally, the temperature sensors 702(1)-702(3) are sometimes referred to herein as “one or more means for sensing temperature of one or more corresponding IC tiers of the plurality of IC tiers.”

Dynamically controlling voltage provided to 3DICs to account for process variations measured across interconnected IC tiers of 3DICs according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

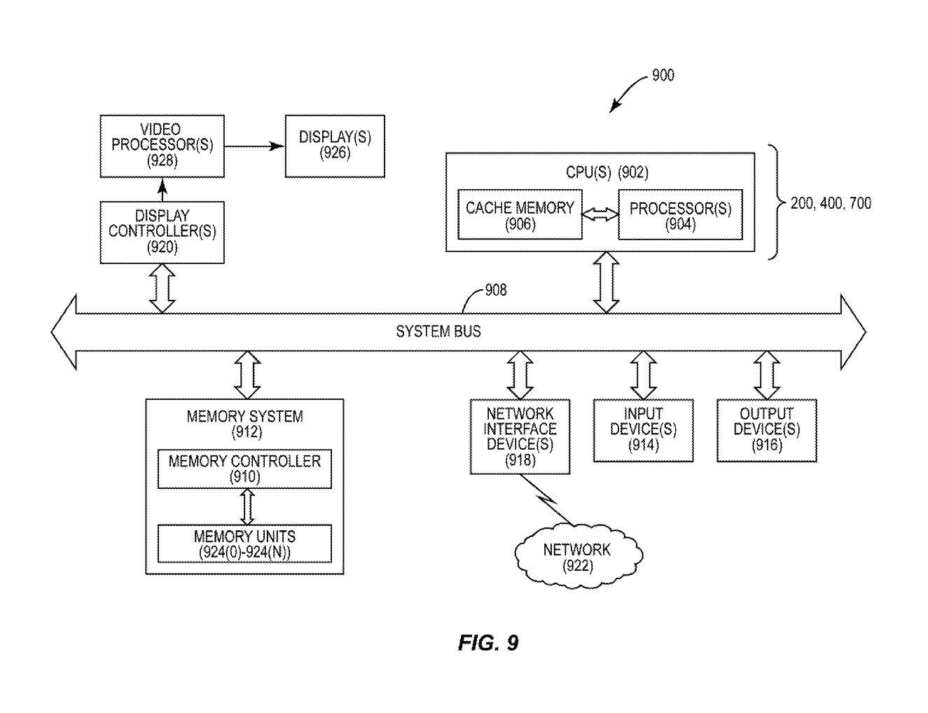

In this regard, FIG. 9 illustrates an example of a processor-based system 900 that can be provided in a 3DIC system that includes a 3DIC PVMC for measuring process variations across interconnected IC tiers of the 3DIC, which can be used by a power management circuit to dynamically control a supply voltage provided to the 3DIC to account for such process variations, including but not limited to the 3DIC systems 200, 400, and 700 of FIGS. 2, 4, and 7, respectively. In this example, the processor-based system 900 includes one or more central processing units (CPUs) 902, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory controller 910 as an example of a slave device. Although not illustrated in FIG. 9, multiple system buses 908 could be provided, wherein each system bus 908 constitutes a different fabric.

Other master and slave devices can be connected to the system bus 908. As illustrated in FIG. 9, these devices can include a memory system 912, one or more input devices 914, one or more output devices 916, one or more network interface devices 918, and one or more display controllers 920, as examples. The input device(s) 914 can include any type of input device, including, but not limited to, input keys, switches, voice processors, etc. The output device(s) 916 can include any type of output device, including, but not limited to, audio, video, other visual indicators, etc. The network interface device(s) 918 can be any device configured to allow exchange of data to and from a network 922. The network 922 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 918 can be configured to support any type of communications protocol desired. The memory system 912 can include one or more memory units 924(0)-924(N).

The CPU(s) 902 may also be configured to access the display controller(s) 920 over the system bus 908 to control information sent to one or more displays 926. The display controller(s) 920 sends information to the display(s) 926 to be displayed via one or more video processors 928, which process the information to be displayed into a format suitable for the display(s) 926. The display(s) 926 can include any type of display, including, but not limited to, a cathode ray tube (CRT), a liquid crystal display (LCD), a plasma display, a light emitting diode (LED) display, etc.

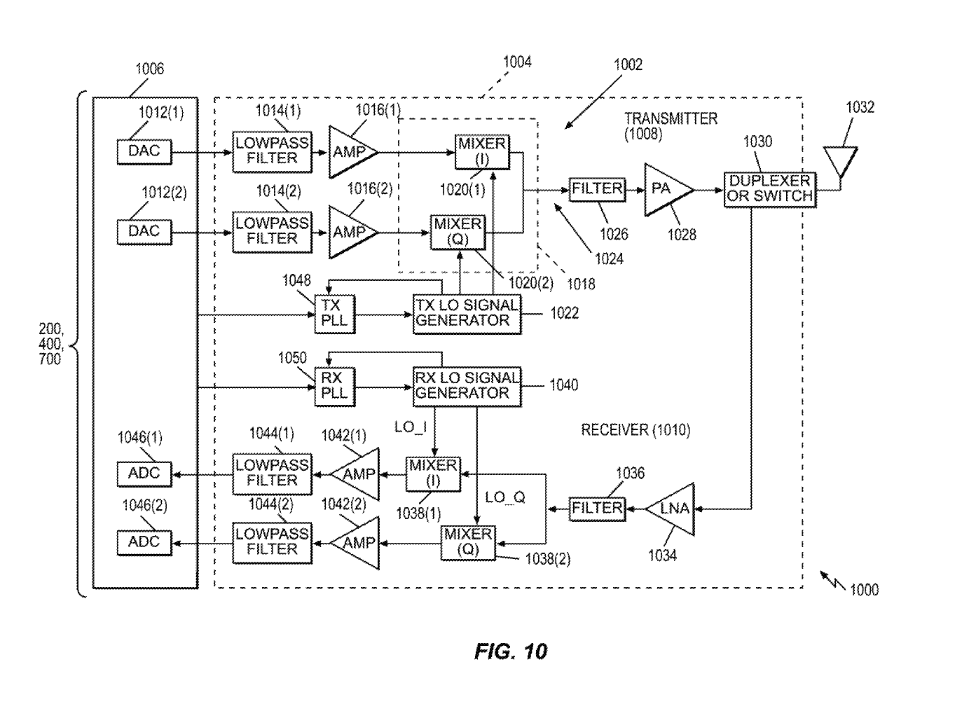

FIG. 10 illustrates an example of a wireless communications device 1000 that can include radio frequency (RF) components, wherein the RF components can be provided in a 3DIC system that includes a 3DIC PVMC for measuring process variations across interconnected IC tiers of the 3DIC, which can be used by a power management circuit to dynamically control a supply voltage provided to the 3DIC to account for such process variations, including but not limited to the 3DIC systems 200, 400, and 700 illustrated in FIGS. 2, 4, and 7, respectively. In this regard, the wireless communications device 1000 may be provided in an IC 1002. The wireless communications device 1000 may include or be provided in any of the above referenced devices, as examples. As shown in FIG. 10, the wireless communications device 1000 includes a transceiver 1004 and a data processor 1006. The data processor 1006 may include a memory (not shown) to store data and program codes. The transceiver 1004 includes a transmitter 1008 and a receiver 1010 that support bi-directional communication. In general, the wireless communications device 1000 may include any number of transmitters and/or receivers for any number of communication systems and frequency bands. All or a portion of the transceiver 1004 may be implemented on one or more analog ICs, RFICs (RFICs), mixed-signal ICs, etc.

A transmitter or a receiver may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog-converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMP) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency upconversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by amplifiers (AMP) 1042(1), 1042(2) and further filtered by lowpass filters 1044(1), 1044(2) to obtain I and Q analog input signals, which are provided to the data processor 1006. In this example, the data processor 1006 includes analog-to-digital-converters (ADCs) 1046(1), 1046(2) for converting the I and Q analog input signals into digital signals to be further processed by the data processor 1006.

In the wireless communications device 1000 in FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the I and Q TX LO signals from the TX LO signal generator 1022. Similarly, a RX phase-locked loop (PLL) circuit 1050 receives timing information from the data processor 1006 and generates a control signal used to adjust the frequency and/or phase of the I and Q RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A three-dimensional (3D) integrated circuit (IC) (3DIC) process variation measurement circuit (PVMC) for measuring process variation across interconnected IC tiers of a 3DIC, the 3DIC PVMC comprising:
a supply voltage input configured to receive a supply voltage coupled to the 3DIC;
one or more stacked logic PVMCs coupled to the supply voltage input, each stacked logic PVMC comprising:
a plurality of logic circuits each comprising one or more measurement transistors of a metal-oxide semiconductor (MOS) type, wherein each logic circuit of the plurality of logic circuits is disposed on a corresponding IC tier of a plurality of IC tiers of the 3DIC; and
a stacked logic measurement output;
each stacked logic PVMC configured to generate, on the corresponding stacked logic measurement output, a stacked process variation measurement voltage signal representing process variation of devices disposed on each corresponding IC tier of the plurality of IC tiers and process variation of a plurality of vias interconnecting the plurality of IC tiers as a function of coupling the supply voltage to the corresponding stacked logic PVMC.

2. The 3DIC PVMC of claim 1, wherein each stacked logic PVMC comprises a stacked ring oscillator circuit comprising the plurality of logic circuits, wherein each stacked ring oscillator circuit comprises:
an odd number of at least three (3) of the plurality of logic circuits each comprising an input node and an output node; and
the stacked logic measurement output coupled to the input node of a first logic circuit and the output node of a final logic circuit.

3. The 3DIC PVMC of claim 2, wherein one or more of the stacked ring oscillator circuits comprise one or more OR-based ring oscillator circuits configured to generate, on the corresponding stacked logic measurement output, the stacked process variation measurement voltage signal representing process variation of P-type MOS (PMOS) devices disposed in the plurality of IC tiers, each OR-based ring oscillator circuit comprising the odd number of at least three (3) of the plurality of logic circuits each comprising an OR-based logic circuit.

4. The 3DIC PVMC of claim 2, wherein one or more of the stacked ring oscillator circuits comprise one or more AND-based ring oscillator circuits configured to generate, on the corresponding stacked logic measurement output, the stacked process variation measurement voltage signal representing process variation of N-type MOS (NMOS) devices disposed in the plurality of IC tiers, each AND-based ring oscillator circuit comprising the odd number of at least three (3) of the plurality of logic circuits each comprising an AND-based logic circuit.

5. The 3DIC PVMC of claim 2, wherein one or more of the stacked ring oscillator circuits is configured to generate, on the corresponding stacked logic measurement output, the stacked process variation measurement voltage signal representing process variation of high voltage threshold transistors disposed on each IC tier of the plurality of IC tiers.

6. The 3DIC PVMC of claim 2, wherein one or more of the stacked ring oscillator circuits is configured to generate, on the corresponding stacked logic measurement output, the stacked process variation measurement voltage signal representing process variation of standard voltage threshold transistors disposed on each IC tier of the plurality of IC tiers.

7. The 3DIC PVMC of claim 2, wherein one or more of the stacked ring oscillator circuits is configured to generate, on the corresponding stacked logic measurement output, the stacked process variation measurement voltage signal representing process variation of low voltage threshold transistors disposed on each IC tier of the plurality of IC tiers.

8. The 3DIC PVMC of claim 1, wherein each logic circuit of the plurality of logic circuits of each stacked logic PVMC is disposed on a different IC tier compared to a previous logic circuit and a next logic circuit of the plurality of logic circuits.

9. The 3DIC PVMC of claim 1, wherein every two logic circuits of the plurality of logic circuits of each stacked logic PVMC is disposed on a different IC tier compared to a previous two logic circuits and a next two logic circuits of the plurality of logic circuits.

10. The 3DIC PVMC of claim 1, further comprising one or more IC tier logic PVMCs disposed in one or more corresponding IC tiers of the plurality of IC tiers and coupled to the supply voltage input, each of the one or more IC tier logic PVMCs comprising:
a plurality of logic circuits each comprising one or more measurement transistors of a MOS type; and
a logic measurement output;
each IC tier logic PVMC configured to generate, on the corresponding logic measurement output, a logic process variation measurement voltage signal representing process variation of devices disposed on the corresponding IC tier of the plurality of IC tiers as a function of coupling the supply voltage to the corresponding IC tier logic PVMC.

11. The 3DIC PVMC of claim 10, wherein each IC tier logic PVMC comprises a ring oscillator circuit comprising the plurality of logic circuits, wherein each ring oscillator circuit comprises:
an odd number of at least three (3) of the plurality of logic circuits each comprising an input node and an output node; and
the logic measurement output coupled to the input node of a first logic circuit and the output node of a final logic circuit.

12. The 3DIC PVMC of claim 11, wherein one or more of the ring oscillator circuits comprises one or more OR-based ring oscillator circuits configured to generate, on the corresponding logic measurement output, the logic process variation measurement voltage signal representing process variation of P-type MOS (PMOS) devices disposed in the corresponding IC tier of the plurality of IC tiers, each OR-based ring oscillator circuit comprising the odd number of at least three (3) of the plurality of logic circuits each comprising an OR-based logic circuit.

13. The 3DIC PVMC of claim 11, wherein one or more of the ring oscillator circuits comprises one or more AND-based ring oscillator circuits configured to generate, on the corresponding logic measurement output, the logic process variation measurement voltage signal representing process variation of N-type MOS (NMOS) devices disposed in the corresponding IC tier of the plurality of IC tiers, each AND-based ring oscillator circuit comprising the odd number of at least three (3) of the plurality of logic circuits each comprising an AND-based logic circuit.

14. The 3DIC PVMC of claim 11, wherein one or more of the ring oscillator circuits is configured to generate, on the corresponding logic measurement output, the logic process variation measurement voltage signal representing process variation of high voltage threshold transistors disposed on the corresponding IC tier of the plurality of IC tiers.

15. The 3DIC PVMC of claim 11, wherein one or more of the ring oscillator circuits is configured to generate, on the corresponding logic measurement output, the logic process variation measurement voltage signal representing process variation of standard voltage threshold transistors disposed on the corresponding IC tier of the plurality of IC tiers.

16. The 3DIC PVMC of claim 11, wherein one or more of the ring oscillator circuits is configured to generate, on the corresponding logic measurement output, the logic process variation measurement voltage signal representing process variation of low voltage threshold transistors disposed on the corresponding IC tier of the plurality of IC tiers.

17. The 3DIC PVMC of claim 1, further comprising one or more temperature sensors disposed in one or more corresponding IC tiers of the 3DIC, wherein each of the one or more temperature sensors is configured to generate a temperature signal of the corresponding IC tier on a corresponding temperature output.

18. The 3DIC PVMC of claim 1 integrated into an IC.

19. The 3DIC PVMC of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

20. A three-dimensional (3D) integrated circuit (IC) (3DIC) process variation measurement circuit (PVMC) for measuring process variation across interconnected IC tiers of a 3DIC, the 3DIC PVMC comprising:
a means for receiving a supply voltage coupled to the 3DIC; and
one or more means for measuring stacked device process variation across a plurality of IC tiers of the 3DIC coupled to the means for receiving the supply voltage;
each of the one or more means for measuring stacked device process variation comprising a means for generating a stacked process variation measurement voltage signal representing process variation of devices disposed on each corresponding IC tier of the plurality of IC tiers and process variation of a plurality of vias interconnecting the plurality of IC tiers as a function of coupling the supply voltage to the corresponding means for measuring stacked device process variation.

21. The 3DIC PVMC of claim 20, further comprising:
a means for coupling the supply voltage to one or more means for measuring IC tier device process variation corresponding to an IC tier of the plurality of IC tiers of the 3DIC coupled to the means for receiving the supply voltage;
each of the one or more means for measuring device process variation comprising a means for generating a logic process variation measurement voltage signal representing process variation of devices disposed on the corresponding IC tier of the plurality of IC tiers as a function of coupling the supply voltage to the corresponding means for measuring device process variation.

22. The 3DIC PVMC of claim 20, further comprising one or more means for sensing temperature of one or more corresponding IC tiers of the 3DIC, each of the one or more means for sensing temperature comprising a means for generating a temperature signal on a corresponding temperature output.

23. A method of measuring process variation across interconnected integrated circuit (IC) tiers of a three-dimensional (3D) IC (3DIC), comprising:
receiving a supply voltage coupled to the 3DIC;
coupling the supply voltage from a supply voltage input to one or more stacked logic process variation measurement circuits (PVMCs), each stacked logic PVMC comprising:
a plurality of logic circuits each comprising one or more measurement transistors of a metal-oxide semiconductor (MOS) type, wherein each logic circuit of the plurality of logic circuits is disposed on a corresponding IC tier of a plurality of IC tiers of the 3DIC; and
a stacked logic measurement output;
generating a stacked process variation measurement voltage signal corresponding to each stacked logic PVMC representing process variation of devices disposed on each corresponding IC tier of the plurality of IC tiers and process variation of a plurality of vias interconnecting the plurality of IC tiers as a function of coupling the supply voltage to the corresponding stacked logic PVMC.

24. The method of claim 23, further comprising:
coupling the supply voltage from the supply voltage input to one or more IC tier logic PVMCs, each IC tier logic PVMC comprising:
a plurality of logic circuits each comprising one or more measurement transistors of a MOS type; and
a logic measurement output;
generating a logic process variation measurement voltage signal corresponding to each IC tier logic PVMC representing process variation of devices disposed on the corresponding IC tier of the plurality of IC tiers as a function of coupling the supply voltage to the corresponding IC tier logic PVMC.

25. The method of claim 23, further comprising:
sensing temperature of each IC tier of the plurality of IC tiers; and
generating a temperature signal of the corresponding IC tier as a function of sensing the temperature.

26. A three-dimensional (3D) integrated circuit (IC) (3DIC) system, comprising:
a power management circuit configured to generate a supply voltage; and
a 3DIC, comprising:
a plurality of IC tiers, each comprising a plurality of devices of a metal-oxide semiconductor (MOS) type;
a plurality of vias interconnecting the plurality of IC tiers; and
a 3DIC PVMC for measuring process variation of devices in the 3DIC, the 3DIC PVMC comprising:
a supply voltage input configured to receive the supply voltage coupled to the 3DIC; and
one or more stacked logic PVMCs coupled to the supply voltage input, each stacked logic PVMC comprising:
a plurality of logic circuits each comprising one or more measurement transistors of the MOS type, wherein each logic circuit of the plurality of logic circuits is disposed on a corresponding IC tier of the plurality of IC tiers of the 3DIC; and
a stacked logic measurement output;
each stacked logic PVMC configured to generate, on the corresponding stacked logic measurement output, a stacked process variation measurement voltage signal representing process variation of devices disposed on each corresponding IC tier of the plurality of IC tiers and process variation of the plurality of vias interconnecting the plurality of IC tiers as a function of coupling the supply voltage to the corresponding stacked logic PVMC;
the power management circuit further configured to:
receive the stacked process variation measurement voltage signal from each stacked logic PVMC;
determine one or more supply voltage levels based on the received stacked process variation measurement voltage signals; and
dynamically generate one or more supply voltages at the determined one or more supply voltage levels.

27. The 3DIC system of claim 26, wherein the 3DIC further comprises:
one or more IC tier logic PVMCs disposed in one or more corresponding IC tiers of the plurality of IC tiers and coupled to the supply voltage input, each of the one or more IC tier logic PVMCs comprising:
a plurality of logic circuits each comprising one or more measurement transistors of a MOS type; and
a logic measurement output;
each IC tier logic PVMC configured to generate, on the corresponding logic measurement output, a logic process variation measurement voltage signal representing process variation of devices disposed on the corresponding IC tier of the plurality of IC tiers as a function of coupling the supply voltage to the corresponding IC tier logic PVMC;
the power management circuit further configured to:
receive the logic process variation measurement voltage signal from each IC tier logic PVMC;
determine one or more supply voltage levels based on the received logic process variation measurement voltage signals and the stacked process variation measurement voltage signals; and
dynamically generate one or more supply voltages at the determined one or more supply voltage levels.

28. The 3DIC system of claim 27, wherein the 3DIC further comprises:
one or more temperature sensors disposed in one or more corresponding IC tiers of the 3DIC, wherein each of the one or more temperature sensors is configured to generate a temperature signal of the corresponding IC tier on a corresponding temperature output;
the power management circuit further configured to:
receive the temperature signal from each of the one or more temperature sensors;
determine the one or more supply voltage levels based on the received temperature signals, the logic process variation measurement voltage signals, and the stacked process variation measurement voltage signals; and
dynamically generate the one or more supply voltages at the determined one or more supply voltage levels.
